(19) United States
(12) Patent Application Publication
(10) Pub. No.: US 2023/0042832 A1
(43) Pub. Date: Feb. 9, 2023

(54) SIC STRUCTURE FORMED BY CVD METHOD

(71) Applicant: TOKAI CARBON KOREA CO., LTD, Gyeonggi-do (KR)

(72) Inventors: Sang Chul LEE, Gyeonggi-do (KR); Yeong Soon PARK, Gyeonggi-do (KR)

(73) Assignee: TOKAI CARBON KOREA CO., LTD, Gyeonggi-do (KR)

(21) Appl. No.: 17/620,273

(22) PCT Filed: Jun. 17, 2020
(86) PCT No.: PCT/KR2020/007850

§ 371 Date: Sep. 22, 2022

(30) Foreign Application Priority Data
Jun. 21, 2019 (KR) 10-2019-0074450

(51) Int. Cl. H01L 21/687; C23C 16/32

(52) U.S. Cl. CPC H01L 21/68757; C23C 16/325

(57) ABSTRACT

The present invention relates to a component for manufacturing a semiconductor manufactured by using a CVD method. A SiC structure formed by the CVD method according to one aspect of the present invention is used such that the SiC structure is exposed to plasma inside a chamber, wherein the SiC structure comprises a crystal grain structure in which the length in a first direction is longer than the length in a second direction when defining a direction perpendicular to the surface most exposed to the plasma as the first direction and a direction horizontal to the surface most exposed to the plasma as the second direction.

### TECHNICAL FIELD

The following description relates to a component for manufacturing a semiconductor including a SiC material, and more particularly, to a structure usable for a dry etching apparatus including a SiC material.

### BACKGROUND ART

Among components used for semiconductor manufacturing equipment, a component exposed to plasma has used single-crystal and columnar silicon. In the case of products of about 500 mm, single-crystal silicon has been used, and in the case of products of 600 mm or more, columnar silicon in which crystal grains are greatly grown has been used due to no single-crystal silicon, and in this case, the purity thereof represents about 99.99999% (6 N).

Recently, with the development of a semiconductor process, the number of layers to be deposited has been rapidly increased, and in order to etch a lot of layers once and make the etched form be perpendicular, high power is used. As such, when the high power is used, there is a problem that silicon, which had been used in the related art, is rapidly etched. In addition, as the time required for the consumption of silicon products is decreased, a lot of time for a frequent internal cleaning problem in the equipment and replacement of consumed components has been required. There was a problem that the problem leads to the loss of production.

To solve these problems, a method of using a material having an excellent anti-plasma property such as SiC as an anti-plasma material has been introduced.

In the related art, in order to increase the use time of the component, the application of an excellent anti-plasma material of oxide, nitride, or carbide materials has been promoted, but components emitted from the etching process and particles generated by the reaction with process gas become a problem and most of the materials cannot be applied. In the case of SiC manufactured by a CVD method, since there was no such particle problem and a 6 N level of ultra-high purity material can be produced, existing silicon components have been replaced.

Recently, studies on the material characteristics of CVD-SiC have continued, and thus, efforts for increasing the anti-plasma property of the products have continued by varying a design of a surface receiving the plasma according to the orientation of the crystal grains.

### DISCLOSURE OF THE INVENTION

### Technical Goals

The present invention is based on the conclusion that is derived after the study of the inventors that recognize the above-mentioned problems and intend to manufacture a SiC structure with its own physical properties.

An aspect provides a structure by introducing a new concept to a method for manufacturing a SiC structure which has been busy introducing conventional SiC materials, so that crystal grains are aligned in a specific direction to improve an anti-plasma property and uniform etching may occur on a surface on which the etching is performed without generating particles in an etching process even if a part of the structure is etched by plasma.

In addition, another aspect provides a SiC structure optimized to etching equipment so as to have superior corrosion resistance by controlling the growth of crystal planes on XRD analysis and adjusting the physical properties according to an alignment direction.

### Technical Solutions

According to an aspect, there is provided a SiC structure formed by a CVD method which is used such that the SiC structure is exposed to plasma inside a chamber, in which the SiC structure includes a crystal grain structure in which the length in a first direction is longer than the length in a second direction when defining a direction perpendicular to the surface most exposed to the plasma as the first direction and a direction horizontal to the surface most exposed to the plasma as the second direction.

According to the example embodiment, the crystal grains may be aligned so as to have a maximum length in −45° to +45° directions based on the first direction.

According to the example embodiment, a value (aspect ratio) of the length in the first direction of the crystal grains/the length in the second direction of the crystal grains may be 1.2 to 20.

According to the example embodiment, the SiC structure may include a first surface which is most exposed to the plasma and developed in a direction perpendicular to the first direction and a second surface which is perpendicular to the first surface and developed in a direction perpendicular to the second direction.

According to the example embodiment, an average strength in the first direction may be 133 Mpa to 200 Mpa and an average strength in the second direction may be 225 Mpa to 260 Mpa.

According to the example embodiment, a value of the average strength in the first direction/the average strength in the second direction may be 0.55 to 0.9.

According to the example embodiment, the resistivity in the first direction may be 3.0×10⁻³ Ωcm to 25 Ωcm, and the resistivity in the second direction may be 1.4×10⁻³ Ωcm to 40 Ωcm.

According to the example embodiment, a value of the resistivity in the first direction/the resistivity in the second direction may be 0.05 to 3.3.

According to the example embodiment, the resistivity in the first direction may be 10 Ωcm to 20 Ωcm, and the resistivity in the second direction may be 21 Ωcm to 40 Ωcm.

According to the example embodiment, a value of the resistivity in the first direction/the resistivity in the second direction may be 0.25 to 0.95.

According to the example embodiment, the resistivity in the first direction may be 0.8 Ωcm to 3.0 Ωcm, and the resistivity in the second direction may be 2.5 Ωcm to 25 Ωcm.

According to the example embodiment, a value of the resistivity in the first direction/the resistivity in the second direction may be 0.04 to 0.99.

According to the example embodiment, the resistivity in the first direction may be 1.8 Ωcm to 3.0 Ωcm, and the resistivity in the second direction may be 0.8 Ωcm to 1.7 Ωcm.

According to the example embodiment, a value of the resistivity in the first direction/the resistivity in the second direction may be 1.15 to 3.2.

According to the example embodiment, the resistivity in the first direction may be 3.0×10⁻³ Ωcm to 5.0×10⁻³ Ωcm, and the resistivity in the second direction may be 1.4×10⁻³ Ωcm to 3.0×10⁻³ Ωcm.

According to the example embodiment, a value of the resistivity in the first direction/the resistivity in the second direction may be 1.1 to 3.3.

According to the example embodiment, the hardness of the SiC structure may be 2800 kg_{f}/mm² to 3300 kg_{f}/mm² regardless of a direction.

According to the example embodiment, a value of the hardness in the first direction/the hardness in the second direction may be 0.85 to 1.15.

According to the example embodiment, with respect to peak intensities in a crystal plane direction for the first direction and the second direction of XRD analysis, [(200+220+311)]/(111) values may be 0.7 to 2.1 in the first direction and 0.4 to 0.75 in the second direction, respectively.

According to the example embodiment, with respect to peak intensities in a crystal plane direction for the first direction and the second direction of XRD analysis, a value of the first direction/the value of the second direction of the [(200+220+311)]/(111) value may be 1.0 to 4.4.

According to the example embodiment, with respect to peak intensities for the first direction and the second direction of XRD analysis, the peak intensities in the (111) crystal plane direction may be 3200 to 10000 in the first direction and 10500 to 17500 in the second direction, respectively.

According to the example embodiment, with respect to peak intensities for the first direction and the second direction of XRD analysis, a value of the peak intensity in the (111) crystal plane direction of the first direction/the peak intensity in the (111) crystal plane direction of the second direction may be 0.2 to 0.95.

According to the example embodiment, the thermal expansion coefficient in the first direction may be 4.0×10⁻⁶/° C. to 4.6×10⁻⁶/° C., and the thermal expansion coefficient in the second direction may be 4.7×10⁻⁶/° C. to 5.4×10⁻⁶/° C.

According to the example embodiment, a value of the thermal expansion coefficient in the first direction/the thermal expansion coefficient in the second direction may be less than 1.0.

According to the example embodiment, a value of the thermal expansion coefficient in the first direction/the thermal expansion coefficient in the second direction may be 0.7 or more and less than 1.0.

According to the example embodiment, the thermal conductivity in the first direction may be 215 W/mk to 260 W/mk, and the thermal conductivity in the second direction may be 280 W/mk to 350 W/mk.

According to the example embodiment, a value of the thermal conductivity in the first direction/the thermal conductivity in the second direction may be less than 1.0.

According to the example embodiment, a value of the thermal conductivity in the first direction/the thermal conductivity in the second direction may be 0.65 to less than 1.0.

According to the example embodiment, the SiC structure may include a first surface which is most exposed to the plasma and developed in a direction perpendicular to the first direction and a second surface which is perpendicular to the first surface and developed in a direction perpendicular to the second direction, in which in the SiC structure, at least a part of the first surface (for example, a lower surface of the SiC structure) may be in contact with a support part.

According to the example embodiment, the SiC structure may be one of an edge ring, a susceptor, and a shower head.

According to the example embodiment, the SiC structure may include a first surface developed in a direction perpendicular to the first direction and a second surface developed in a direction perpendicular to the second direction, in which the total sum of areas of the first surface may be larger than the total sum of areas of the second surface.

### Advantageous Effects

According to the present invention, it is possible to manufacture a SiC structure that improves the anti-plasma property and increases a replacement cycle. Further, the SiC structure proposed in the present invention may lower the occurrence frequency of cracks or holes due to a low etching rate by plasma and reduce a scattering rate of materials causing the manufacturing of defective products by polluting the inside of the chamber.

According to the example embodiment of the present invention, in the SiC structure, since crystal grains are aligned in a specific direction, the SiC structure has effects of maintaining a uniform resistivity even if a part of the structure is etched by plasma and improving an adhesion effect of heterogeneous materials such as polymers and the like in the etching process by preventing a charge accumulation effect caused by resistance.

Further, it is possible to provide a SiC structure in which a resistivity in a specific direction is controlled to an appropriate level according to the purpose and to provide a SiC structure with increased corrosion resistance and secured etching uniformity through the control of a crystal surface on XRD analysis.

In addition, according to the example embodiment of the present invention, it may be expected to prevent the charge accumulation on a plasma-exposed surface of the SiC structure due to a low resistivity value in a specific direction and improve a polymer adhesion phenomenon in the etching process by improving a charging phenomenon of the SiC structure.

In addition, according to the example embodiment of the present invention, it is possible to improve efficient heat transfer efficiency in a specific direction and adjust a plasma etching depth to an accurate degree even in the etching process performed in the state where the temperature rises, by controlling a thermal conductivity value and a thermal expansion coefficient value in the specific direction.

Due to the contents proposed in the present invention, it is possible to design components of a semiconductor manufacturing apparatus using the SiC structure proposed in the present invention, increase a replacement cycle of the corresponding components, and improve the quality of the semiconductor components manufactured therefrom, thereby manufacturing a high-quality semiconductor device.

### BRIEF DESCRIPTION OF DRAWINGS

FIG. 1A is a cross-sectional view schematically illustrating an inner structure of a general plasma chamber mounted with a SiC structure according to an example embodiment of the present invention, FIG. 1B is a cross-sectional view illustrating a structure in which a wafer is mounted on an edge ring in yet another general plasma chamber, as an example of the SiC structure according to the example embodiment of the present invention, and FIG. 1C is a schematic diagram illustrating a first surface and a second surface defined in the edge ring corresponding to an example of the SiC structure according to the example embodiment of the present invention.

FIGS. 2A and 2B are cross-sectional views schematically illustrating crystal grain shapes included in a cross section (FIG. 2A) cut in a first direction and a cross section (FIG. 2B) cut in a second direction of the SiC structure according to the example embodiment of the present invention, and FIGS. 2C and 2D are SEM photographs of the SiC structure according to the example embodiment of the present invention corresponding to FIGS. 2A and 2B.

FIGS. 3A to 3F are SEM photographs illustrating a process of measuring sizes in a first direction and a second direction of crystal grains in the cross section cut in the first direction of the SiC structure according to the example embodiment of the present invention.

FIG. 4 is a graph showing distribution of strength values measured in the first direction and the second direction in the SiC structure according to the example embodiment of the present invention.

FIGS. 5A to 5D are graphs showing distribution of resistivity values (a structure having a second direction of about 30 Ωcm, a structure having a second direction of about 10 Ωcm, a structure having a second direction of about 1 Ωcm, and a structure having a second direction of 1 Ωcm or less) measured in the first direction and the second direction in the SiC structure according to the example embodiment of the present invention.

FIG. 6 is a graph showing distribution of hardness values measured in the first direction and the second direction in the SiC structure according to the example embodiment of the present invention.

FIG. 7 is a graph showing distribution of diffraction intensity values of a (111) crystal plane of XRD analysis values measured in the first direction and the second direction in the SiC structure according to the example embodiment of the present invention.

FIGS. 8A and 8B are diagrams illustrating a schematic method of measuring strengths in a first direction (FIG. 8A) and a second direction (FIG. 8B) in the SiC structure according to the example embodiment of the present invention.

FIGS. 9A and 9B are diagrams illustrating a schematic method of measuring resistivities in a first direction (FIG. 9A) and a second direction (FIG. 9B) in the SiC structure according to the example embodiment of the present invention.

FIGS. 10A and 10B are diagrams illustrating a schematic method of measuring hardness in a first direction (FIG. 10A) and a second direction (FIG. 10B) in the SiC structure according to the example embodiment of the present invention.

FIGS. 11A and 11B are diagrams illustrating a schematic method of performing XRD diffraction analysis in a first direction (FIG. 11A) and a second direction (FIG. 11B) in the SiC structure according to the example embodiment of the present invention.

FIGS. 12A and 12B are diagrams illustrating a schematic method of performing thermal expansion rate analysis in a first direction (FIG. 12A) and a second direction (FIG. 12B) in the SiC structure according to the example embodiment of the present invention.

FIGS. 13A and 13B are diagrams illustrating a schematic method of performing thermal conductivity analysis in a first direction (FIG. 13A) and a second direction (FIG. 13B) in the SiC structure according to the example embodiment of the present invention.

FIG. 14 is a photograph showing a microstructure (crystal grain structure) of a cross section in a first direction and a cross section in a second direction in the SiC structure according to the example embodiment of the present invention and an SEM photograph showing an etched form when the corresponding microstructure is exposed to plasma.

FIG. 15 is a graph of analyzing a plasma etching amount in a first direction and a plasma etching amount in a second direction in the SiC structure according to the example embodiment of the present invention.

### BEST MODE FOR CARRYING OUT THE INVENTION

Hereinafter, example embodiments will be described in detail with reference to the accompanying drawings.

Various modifications may be made to example embodiments to be described below. Example embodiments to be described below are not intended to be limited to aspects and should be understood to include all modifications, equivalents, and substitutes thereof.

Terminologies used herein are used only to describe specific example embodiments, and are not intended to limit the example embodiments. Singular expressions used herein include plurals expressions unless they have definitely opposite meanings in the context. In the present specification, it should be understood that the term “comprising” or “having” indicates that a feature, a number, a step, an operation, a component, a part or a combination thereof which are described are present, but does not exclude a possibility of presence or addition of one or more other features, numbers, steps, operations, components, parts or combinations thereof, in advance.

Unless otherwise contrarily defined, all terms used herein including technological or scientific terms have the same meanings as those generally understood by a person with ordinary skill in the art to which example embodiments pertain. Terms which are defined in a generally used dictionary should be interpreted to have the same meaning as the meaning in the context of the related art, and are not interpreted as an ideal meaning or excessively formal meanings unless otherwise defined in the present application.

In addition, in the description with reference to the accompanying drawings, like components regardless of reference numerals designate like reference numerals and a duplicated description thereof will be omitted. In describing the example embodiments, a detailed description of related known technologies will be omitted if it is determined that they unnecessarily make the gist of the example embodiments unclear.

In general, a SiC material grown by a CVD method is known to have a cubic structure of β-SiC, in which a crystal form thereof has a zinc blende structure similar to silicon. Accordingly, in the crystal structure of the silicon, when a crystal direction faces a (111) plane, the coordinate number per unit area is most shown. Thus, a CVD SiC material may also have the most coordinate number of 3 in the same (111)-plane direction.

The increased coordinate number per unit volume means that when the material is exposed to plasma in the corresponding plane direction, an anti-plasma property (plasma resistance) is relatively increased. Accordingly, even in the same material, aligning a crystal plane in a direction having a large coordinate number per unit area is an important principle to improve the quality of an anti-plasma material. In the case of the SiC material grown by the CVD method, a side having a large amount of crystal grains in the (111) direction is designed as a plane to be exposed to the plasma, so that the surface of the SiC structure may be designed to have a high anti-plasma property.

Further, in the SiC material grown by the CVD method, the anti-plasma property is also affected by the orientation and uniform alignment of the crystal grains. When comparing large crystal grains with relatively small crystal grains of the crystal grains, when the small crystal grains are formed when exposed to the plasma, first, the crystal grains are deviated or etched so that the etching is shown in the form of penetrating into the material. When exposed to stronger plasma or exposed to the plasma longer, the large crystal grains also deviate, and in this case, a phenomenon in which the etching thickness is rapidly increased is shown. Accordingly, the orientation and the size distribution of the crystal grains are important factors affecting the etching characteristics of the SiC structure.

Meanwhile, in the SiC structure, the designing and processing of the physical properties of the SiC structure based on a specific surface to which the plasma is mainly reached may become a factor for increasing the anti-plasma property.

In the present invention, a surface that is most exposed to the plasma in the SiC structure is defined as a first surface 100a of the SiC structure. A direction (a direction in which the plasma approaches the SiC structure) perpendicular to the first surface to be most exposed to the plasma is defined as a first direction. As an example, the first direction may correspond to a height direction of a chamber, i.e., a height direction of an edge ring. At this time, in the case of designing a product so that the plasma is most introduced to the SiC structure in a direction other than the first direction described above, as soon as the plasma is reached, the rapid etching occurs through the deviation of the small crystal grains and ununiform etching may occur. In addition, in a severe case, the large crystal grains also deviate, and a problem caused by scattered particles may occur.

As described above, when manufacturing a component with such a material, which surface is designed in any orientation may be an important issue in strengthening the anti-plasma property of the material.

The present invention is to propose an SiC structure such as an edge ring, a shower head, or the like which has an excellent anti-plasma property to increase a replacement cycle and improve productivity and may stably produce a component for manufacturing a high-quality semiconductor. When the SiC structure proposed in the present invention is applied to a dry etching apparatus in an environment to be exposed to plasma shining down from the top, there is an advantage that an amount to be etched is small to reduce a scattering amount. Further, the SiC structure of the present invention has an advantage of manufacturing components for manufacturing a semiconductor with excellent quality while reducing production costs such as an increased replacement cycle and the like as compared with a conventional structure.

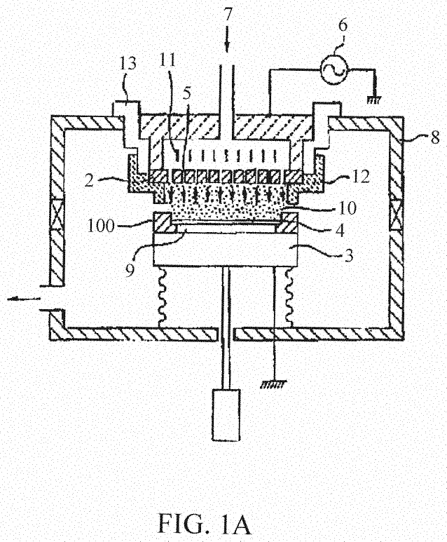

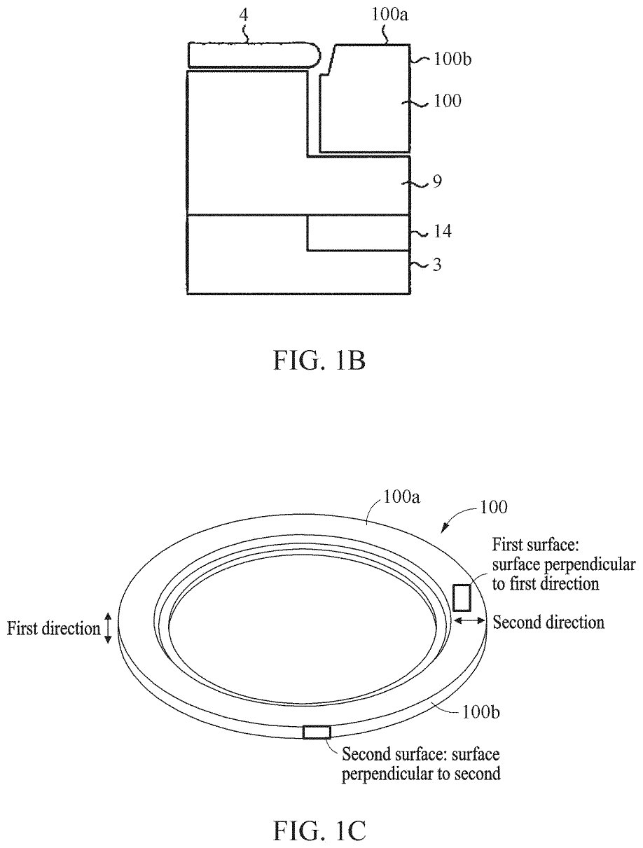

FIG. 1A is a cross-sectional view schematically illustrating an inner structure of a general plasma chamber mounted with a SiC structure according to an example embodiment of the present invention, FIG. 1B is a cross-sectional view illustrating a structure in which a wafer is mounted on an edge ring in yet another general plasma chamber, as an example of the SiC structure according to the example embodiment of the present invention, and FIG. 1C is a schematic diagram illustrating a first surface 100a and a second surface 100b defined in the edge ring corresponding to an example of the SiC structure according to the example embodiment of the present invention.

Through FIG. 1A, a plasma chamber using the SiC structure proposed in the present invention may be confirmed, and through FIGS. 1B and 1C, how a first direction, a second direction, a first surface, and a second surface are defined in the SiC structure proposed as an example may be confirmed.

An edge ring as one of the SiC structures proposed in the present invention may be specifically implemented in various forms according to a position on which a wafer is seated, but basically, the edge ring may be mounted in a form illustrated in FIGS. 1A and 1B with a flat ring-shaped structure or cylindrical structure as illustrated in FIG. 1C. However, basically, since the edge ring generally has a shape having a width larger than the height, the edge ring is more preferably referred to as a ring-shaped structure.

At this time, the SiC structure may be manufactured so that there is a difference between a physical property measured in the first direction and a physical property measured in the second direction of the edge ring, or the ratio thereof is controlled at an appropriate level.

This is because since the SiC structure is not uniformly etched by the plasma in all directions, a high level of physical properties are maintained in an approaching and introducing direction of a large amount of plasma and a relatively low level of physical properties are maintained in an approaching direction of a relatively small amount of plasma. In addition, the reason is that components may be designed so as to efficiently implement excellent structural, thermal, and electrical performances in the plasma chamber.

In the material development, much more effort and cost is required for developing the material to achieve a required level of physical properties than identifying the physical properties as values. In the case of manufacturing the SiC structure to implement a high level of physical properties (strength, hardness, crystal grain size, thermal conductivity, thermal expansion coefficient, etc.) in all directions, an excellent SiC structure may be manufactured, but there is a problem that high cost and technology are required to design the SiC structure to meet such a physical property level.

The present invention relates to a result of conducting the study on a deposition method of the SiC material capable of increasing process productivity and reducing the costs even while maintaining an excellent level of anti-plasma property when being mounted on a dry etching apparatus.

Hereinafter, the SiC structure designed in the present invention will be described in detail.

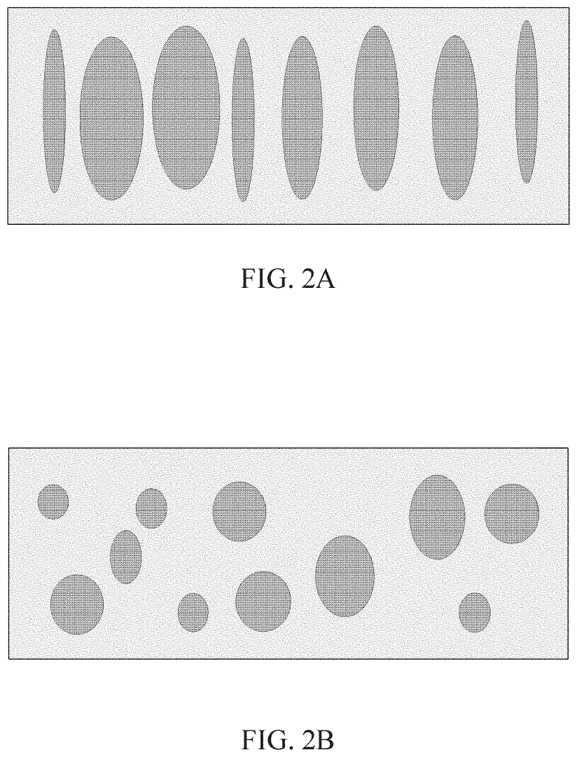

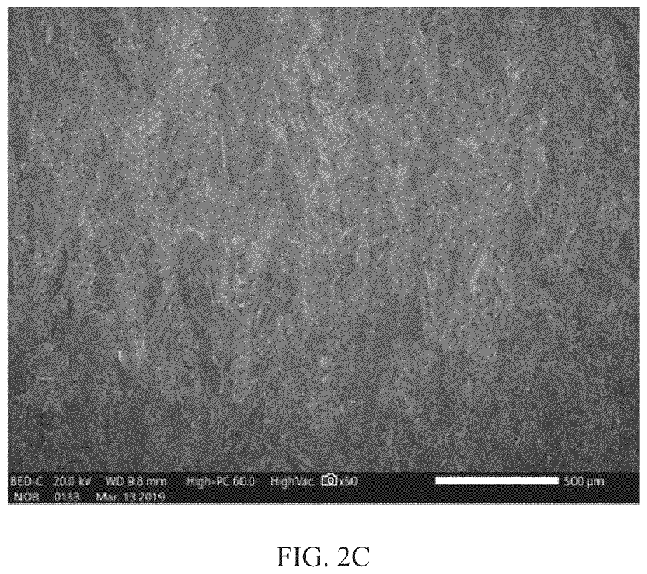

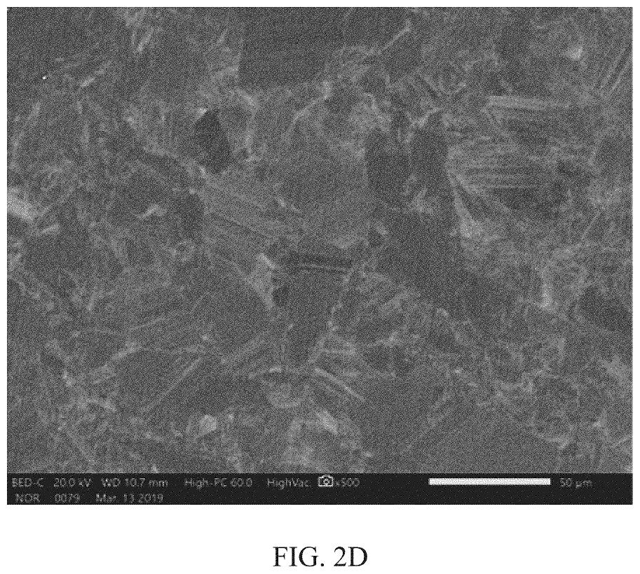

FIGS. 2A and 2B are cross-sectional views schematically illustrating crystal grain shapes included in a cross section (FIG. 2A) cut in a first direction and a cross section (FIG. 2B) cut in a second direction of the SiC structure according to the example embodiment of the present invention, and FIGS. 2C and 2D are SEM photographs of the SiC structure according to the example embodiment of the present invention corresponding to FIGS. 2A and 2B.

When an example of the SiC structure proposed in the present invention is described with reference to FIGS. 2A to 2D, crystal grains of the SiC structure may be formed in a relatively longer shape on a surface cut in a first direction than a second direction. As such, when the crystal grains formed longer in a specific direction are included, it is possible to design and implement an advantageous effect on the product due to the crystal grain directivity when defects or etching occur.

According to one aspect of the present invention, there is provided a SiC structure formed by a CVD method used such that the SiC structure is exposed to plasma inside a chamber, in which the SiC structure includes a crystal grain structure in which the length in a first direction is longer than the length in a second direction when defining a direction perpendicular to the surface most exposed to the plasma as the first direction and a direction horizontal to the surface most exposed to the plasma as the second direction.

The SiC structure includes a crystal grain structure that is formed relatively long in the first direction, and such a structure may be easily identified with naked eyes by identifying by an SEM, a polarizing microscope, and the like.

According to the example embodiment, the crystal grains may be aligned to have a maximum length in −45° to +45° directions based on the first direction. All of the crystal grains may not be aligned in a direction completely coinciding with the first direction, but a direction formed with long lengths of the crystal grains may be a direction close to the first direction, and as an example, crystal grains grown at an angle of −30° to +30° based on the first direction may be included.

According to the example embodiment, a value (aspect ratio) of the length in the first direction of the crystal grains/the length in the second direction of the crystal grains may be 1.2 to 20.

A ratio of the size in the first direction/the size in the second direction of the crystal grains may be, for example, 2.5 or more, preferably 17.5 or less. The size ratio may be, for example, 1.25 or more and 9.0 or less. The crystal grains may be implemented in the form of a needle shape as the length in the first direction is increased.

The length in the first direction of the SiC structure may be 1.2 times to at least about 20 times larger than the length in the second direction. As an example, the size may be an average size.

With respect to the SiC structure proposed in the present invention, specimens with sizes of 20 mm×10 mm×5 mm are prepared and the sizes in the first direction and the second direction of the crystal grains are measured based on 500× magnifications using SEM equipment with respect to total 175 points, and the result thereof was analyzed.

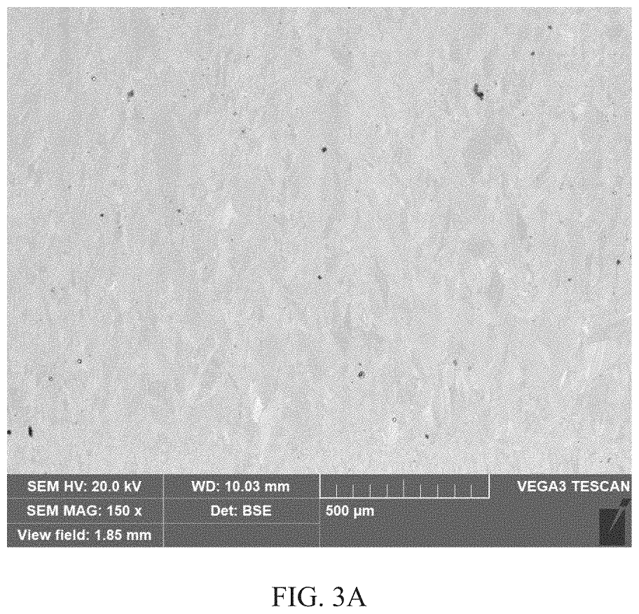

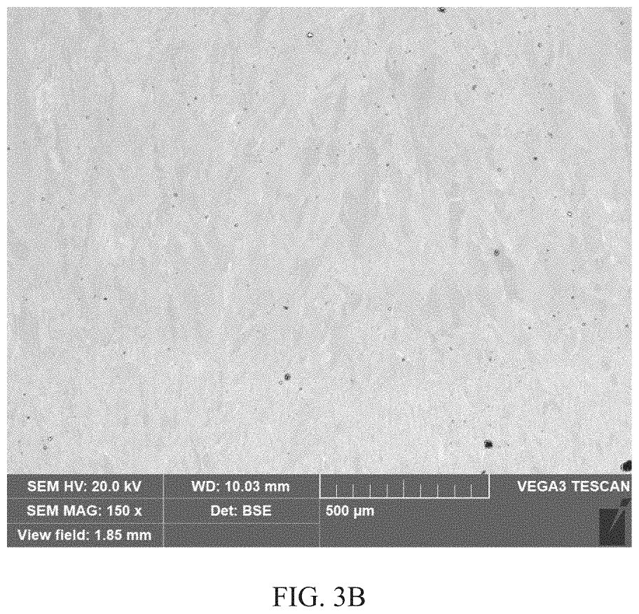

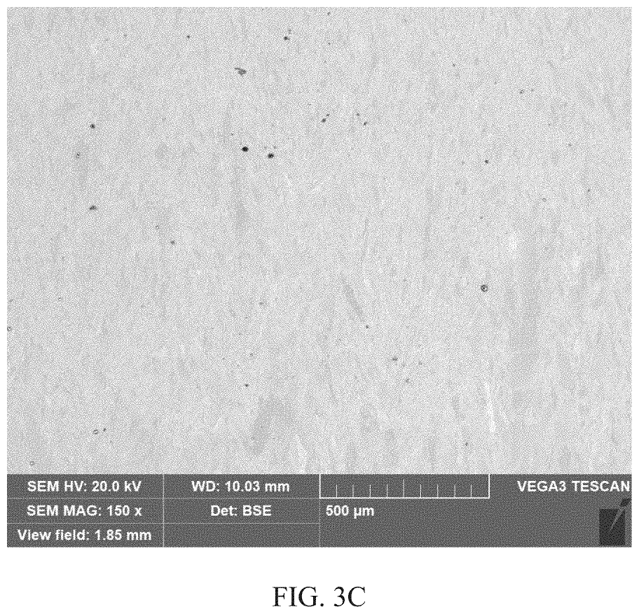

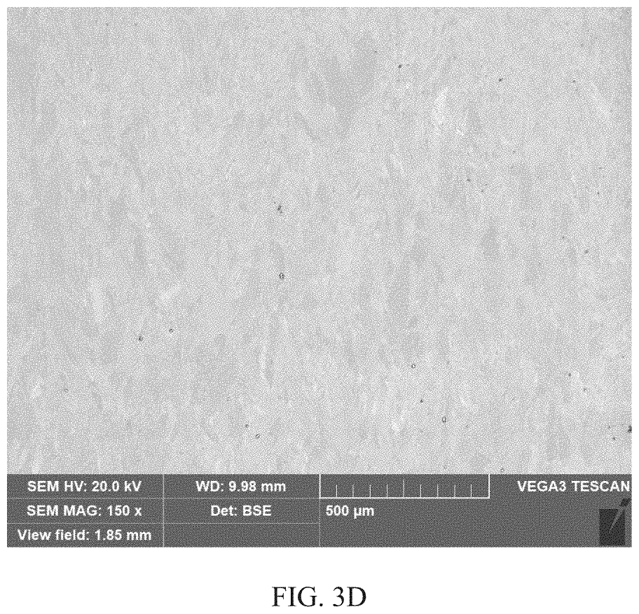

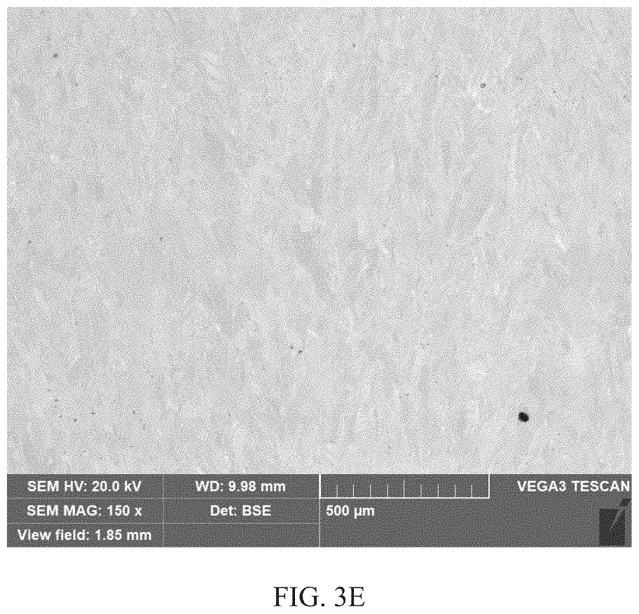

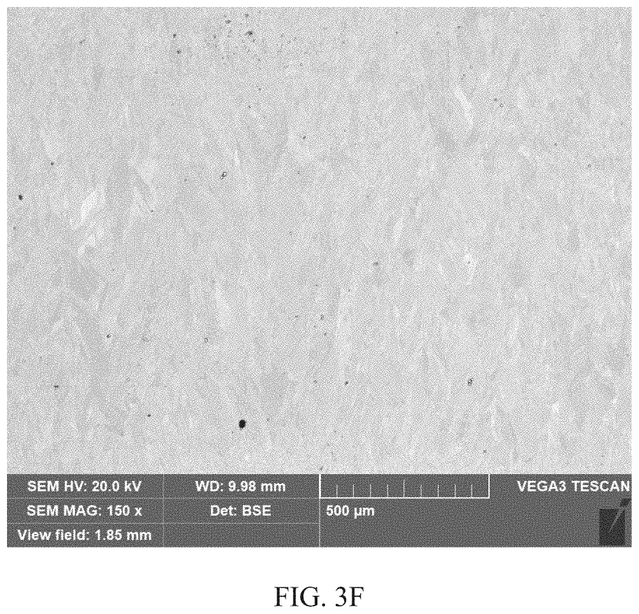

FIG. 3 is an SEM photograph showing a process of measuring a crystal grain size in a cross section in the first direction of the SiC structure as an example of the SiC structure according to the example embodiment of the present invention.

As illustrated in FIGS. 3A to 3F, a portion referred to as the crystal grain in the present invention means a portion shown as a relatively dark color on the microstructure photograph in the cross section of the SiC structure. As described above through FIGS. 3A to 3F, it can be confirmed that the crystal grains are aligned around the first direction.

Table 1 below shows values of sizes and ratios of the crystal grains measured in each direction over total 175 times using the SiC structure of the present invention as described above.

TABLE 1
Analysis of crystal grain size

| Measurement 1 | First direction | Second direction | [symbol] |
|---|---|---|---|
| 1 | [symbol] | [symbol] | [symbol] |
| 2 | [symbol] | [symbol] | [symbol] |
| 3 | [symbol] | [symbol] | [symbol] |
| 4 | [symbol] | [symbol] | [symbol] |
| 5 | [symbol] | [symbol] | [symbol] |
| 6 | [symbol] | [symbol] | [symbol] |
| 7 | [symbol] | [symbol] | [symbol] |
| 8 | [symbol] | [symbol] | [symbol] |
| 9 | [symbol] | [symbol] | [symbol] |
| 10 | [symbol] | [symbol] | [symbol] |
| 11 | [symbol] | [symbol] | [symbol] |
| 12 | [symbol] | [symbol] | [symbol] |
| 13 | [symbol] | [symbol] | [symbol] |
| 14 | [symbol] | [symbol] | [symbol] |
| 15 | [symbol] | [symbol] | [symbol] |
| 16 | [symbol] | [symbol] | [symbol] |
| 17 | [symbol] | [symbol] | [symbol] |
| 18 | [symbol] | [symbol] | [symbol] |
| 19 | [symbol] | [symbol] | [symbol] |
| 20 | [symbol] | [symbol] | [symbol] |
| 21 | [symbol] | [symbol] | [symbol] |
| 22 | [symbol] | [symbol] | [symbol] |
| 23 | [symbol] | [symbol] | [symbol] |
| 24 | [symbol] | [symbol] | [symbol] |
| 25 | [symbol] | [symbol] | [symbol] |
| 26 | [symbol] | [symbol] | [symbol] |
| 27 | [symbol] | [symbol] | [symbol] |
| 28 | [symbol] | [symbol] | [symbol] |
| 29 | [symbol] | [symbol] | [symbol] |
| 30 | [symbol] | [symbol] | [symbol] |
| 31 | [symbol] | [symbol] | [symbol] |
| 32 | [symbol] | [symbol] | [symbol] |
| 33 | [symbol] | [symbol] | [symbol] |
| 34 | [symbol] | [symbol] | [symbol] |
| 35 | [symbol] | [symbol] | [symbol] |
| 36 | [symbol] | [symbol] | [symbol] |
| 37 | [symbol] | [symbol] | [symbol] |
| 38 | [symbol] | [symbol] | [symbol] |
| 39 | [symbol] | [symbol] | [symbol] |
| 40 | [symbol] | [symbol] | [symbol] |
| 41 | [symbol] | [symbol] | [symbol] |
| 42 | [symbol] | [symbol] | [symbol] |
| 43 | [symbol] | [symbol] | [symbol] |
| 44 | [symbol] | [symbol] | [symbol] |
| 45 | [symbol] | [symbol] | [symbol] |
| 46 | [symbol] | [symbol] | [symbol] |
| 47 | [symbol] | [symbol] | [symbol] |
| 48 | [symbol] | [symbol] | [symbol] |
| 49 | [symbol] | [symbol] | [symbol] |
| 50 | [symbol] | [symbol] | [symbol] |
| 51 | [symbol] | [symbol] | [symbol] |
| 52 | [symbol] | [symbol] | [symbol] |
| 53 | [symbol] | [symbol] | [symbol] |
| 54 | [symbol] | [symbol] | [symbol] |
| 55 | [symbol] | [symbol] | [symbol] |
| 56 | [symbol] | [symbol] | [symbol] |
| 57 | [symbol] | [symbol] | [symbol] |
| 58 | [symbol] | [symbol] | [symbol] |
| 59 | [symbol] | [symbol] | [symbol] |
| 60 | [symbol] | [symbol] | [symbol] |
| 61 | [symbol] | [symbol] | [symbol] |
| 62 | [symbol] | [symbol] | [symbol] |
| 63 | [symbol] | [symbol] | [symbol] |
| 64 | [symbol] | [symbol] | [symbol] |
| 65 | [symbol] | [symbol] | [symbol] |
| 66 | [symbol] | [symbol] | [symbol] |
| 67 | [symbol] | [symbol] | [symbol] |
| 68 | [symbol] | [symbol] | [symbol] |
| 69 | [symbol] | [symbol] | [symbol] |
| 70 | [symbol] | [symbol] | [symbol] |
| 71 | [symbol] | [symbol] | [symbol] |
| 72 | [symbol] | [symbol] | [symbol] |
| 73 | [symbol] | [symbol] | [symbol] |
| 74 | [symbol] | [symbol] | [symbol] |
| 75 | [symbol] | [symbol] | [symbol] |
| 76 | [symbol] | [symbol] | [symbol] |
| 77 | [symbol] | [symbol] | [symbol] |
| 78 | [symbol] | [symbol] | [symbol] |
| 79 | [symbol] | [symbol] | [symbol] |
| 80 | [symbol] | [symbol] | [symbol] |
| 81 | [symbol] | [symbol] | [symbol] |
| 82 | [symbol] | [symbol] | [symbol] |
| 83 | [symbol] | [symbol] | [symbol] |
| 84 | [symbol] | [symbol] | [symbol] |
| 85 | [symbol] | [symbol] | [symbol] |
| 86 | [symbol] | [symbol] | [symbol] |
| 87 | [symbol] | [symbol] | [symbol] |
| 88 | [symbol] | [symbol] | [symbol] |
| 89 | [symbol] | [symbol] | [symbol] |
| 90 | [symbol] | [symbol] | [symbol] |
| 91 | [symbol] | [symbol] | [symbol] |
| 92 | [symbol] | [symbol] | [symbol] |
| 93 | [symbol] | [symbol] | [symbol] |
| 94 | [symbol] | [symbol] | [symbol] |
| 95 | [symbol] | [symbol] | [symbol] |
| 96 | [symbol] | [symbol] | [symbol] |
| 97 | [symbol] | [symbol] | [symbol] |
| 98 | [symbol] | [symbol] | [symbol] |
| 99 | [symbol] | [symbol] | [symbol] |
| 100 | [symbol] | [symbol] | [symbol] |
| Measurement 2 | First direction | Second direction | [symbol] |
| 1 | [symbol] | [symbol] | [symbol] |
| 2 | [symbol] | [symbol] | [symbol] |
| 3 | [symbol] | [symbol] | [symbol] |
| 4 | [symbol] | [symbol] | [symbol] |
| 5 | [symbol] | [symbol] | [symbol] |
| 6 | [symbol] | [symbol] | [symbol] |
| 7 | [symbol] | [symbol] | [symbol] |
| 8 | [symbol] | [symbol] | [symbol] |
| 9 | [symbol] | [symbol] | [symbol] |
| 10 | [symbol] | [symbol] | [symbol] |
| 11 | [symbol] | [symbol] | [symbol] |
| 12 | [symbol] | [symbol] | [symbol] |
| 13 | [symbol] | [symbol] | [symbol] |
| 14 | [symbol] | [symbol] | [symbol] |
| 15 | [symbol] | [symbol] | [symbol] |
| 16 | [symbol] | [symbol] | [symbol] |
| 17 | [symbol] | [symbol] | [symbol] |
| 18 | [symbol] | [symbol] | [symbol] |
| 19 | [symbol] | [symbol] | [symbol] |
| 20 | [symbol] | [symbol] | [symbol] |
| 21 | [symbol] | [symbol] | [symbol] |
| 22 | [symbol] | [symbol] | [symbol] |
| 23 | [symbol] | [symbol] | [symbol] |
| 24 | [symbol] | [symbol] | [symbol] |
| 25 | [symbol] | [symbol] | [symbol] |
| 26 | [symbol] | [symbol] | [symbol] |
| 27 | [symbol] | [symbol] | [symbol] |
| 28 | [symbol] | [symbol] | [symbol] |
| 29 | [symbol] | [symbol] | [symbol] |
| 30 | [symbol] | [symbol] | [symbol] |
| 31 | [symbol] | [symbol] | [symbol] |
| 32 | [symbol] | [symbol] | [symbol] |
| 33 | [symbol] | [symbol] | [symbol] |
| 34 | [symbol] | [symbol] | [symbol] |
| 35 | [symbol] | [symbol] | [symbol] |
| 36 | [symbol] | [symbol] | [symbol] |
| 37 | [symbol] | [symbol] | [symbol] |
| 38 | [symbol] | [symbol] | [symbol] |
| 39 | [symbol] | [symbol] | [symbol] |
| 40 | [symbol] | [symbol] | [symbol] |
| 41 | [symbol] | [symbol] | [symbol] |
| 42 | [symbol] | [symbol] | [symbol] |
| 43 | [symbol] | [symbol] | [symbol] |
| 44 | [symbol] | [symbol] | [symbol] |
| 45 | [symbol] | [symbol] | [symbol] |
| 46 | [symbol] | [symbol] | [symbol] |
| 47 | [symbol] | [symbol] | [symbol] |
| 48 | [symbol] | [symbol] | [symbol] |
| 49 | [symbol] | [symbol] | [symbol] |
| 50 | [symbol] | [symbol] | [symbol] |
| 51 | [symbol] | [symbol] | [symbol] |
| 52 | [symbol] | [symbol] | [symbol] |
| 53 | [symbol] | [symbol] | [symbol] |
| 54 | [symbol] | [symbol] | [symbol] |
| 55 | [symbol] | [symbol] | [symbol] |
| 56 | [symbol] | [symbol] | [symbol] |
| 57 | [symbol] | [symbol] | [symbol] |
| 58 | [symbol] | [symbol] | [symbol] |
| 59 | [symbol] | [symbol] | [symbol] |
| 60 | [symbol] | [symbol] | [symbol] |
| 61 | [symbol] | [symbol] | [symbol] |
| 62 | [symbol] | [symbol] | [symbol] |
| 63 | [symbol] | [symbol] | [symbol] |
| 64 | [symbol] | [symbol] | [symbol] |
| 65 | [symbol] | [symbol] | [symbol] |
| 66 | [symbol] | [symbol] | [symbol] |
| 67 | [symbol] | [symbol] | [symbol] |
| 68 | [symbol] | [symbol] | [symbol] |
| 69 | [symbol] | [symbol] | [symbol] |
| 70 | [symbol] | [symbol] | [symbol] |
| 71 | [symbol] | [symbol] | [symbol] |
| 72 | [symbol] | [symbol] | [symbol] |
| 73 | [symbol] | [symbol] | [symbol] |
| 74 | [symbol] | [symbol] | [symbol] |
| 75 | [symbol] | [symbol] | [symbol] |

[symbol]

indicates data missing or illegible when filed

According to the example embodiment, the SiC structure may include a first surface which is most exposed to the plasma and developed in a direction perpendicular to the first direction and a second surface which is perpendicular to the first surface and developed in a direction perpendicular to the second direction.

As an example of the SiC structure proposed in the present invention, with respect to the SiC structure, 10 specimens with sizes of 1 mm (length)×2 mm (width)×10 mm (height) are prepared to measure strength values in the first direction and the second direction and analyze the result thereof.

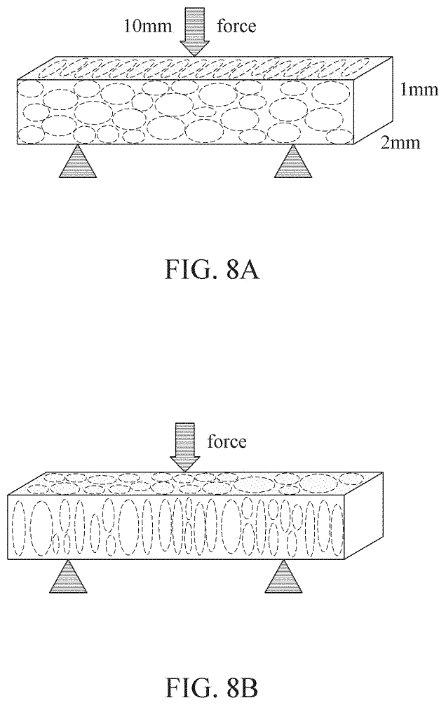

FIGS. 8A and 8B are diagrams illustrating a schematic method of measuring strengths in a first direction (FIG. 8A) and a second direction (FIG. 8B) in the SiC structure according to the example embodiment of the present invention.

The strengths were measured using a universal testing machine (UTM, manufactured by UNITECH), and the specimens were fabricated as possible as small for Ring material analysis and the analysis was performed by measuring 3-curved point bending strength.

An interatomic distance was adjusted to 2 mm and measured by cross head speed of 0.5 mm/min and a span of 11 mm and other specimen fabrication, and measurement were measured according to KSL 1591. Each strength value was measured by applying a force directly in the direction perpendicular to the first surface and in the direction perpendicular to the second surface to be measured during measuring.

Table 2 below shows values of measuring the sizes and ratios of the strengths measured in the first direction and the second direction with respect to 10 specimens using the SiC structure as an example of the SiC structure of the present invention as described above.

TABLE 2
Analysis of strength

| | [symbol] | | | | | | | |
|---|---|---|---|---|---|---|---|---|
| | First direction | | | | Second direction | | | |
| | [symbol] | | | | | | | |
| | 0.5 mm/min | | [symbol] | [symbol] | 0.5 mm/min | | [symbol] | [symbol] |
| Sample No. | [symbol] | [symbol] | [symbol] | [symbol] | [symbol] | [symbol] | [symbol] | [symbol] |
| 1 | [symbol] | [symbol] | [symbol] | [symbol] | [symbol] | [symbol] | [symbol] | [symbol] |
| 2 | [symbol] | [symbol] | [symbol] | [symbol] | [symbol] | [symbol] | [symbol] | [symbol] |
| 3 | [symbol] | [symbol] | [symbol] | [symbol] | [symbol] | [symbol] | [symbol] | [symbol] |
| 4 | [symbol] | [symbol] | [symbol] | [symbol] | [symbol] | [symbol] | [symbol] | [symbol] |
| 5 | [symbol] | [symbol] | [symbol] | [symbol] | [symbol] | [symbol] | [symbol] | [symbol] |
| 6 | [symbol] | [symbol] | [symbol] | [symbol] | [symbol] | [symbol] | [symbol] | [symbol] |
| 7 | [symbol] | [symbol] | [symbol] | [symbol] | [symbol] | [symbol] | [symbol] | [symbol] |
| 8 | [symbol] | [symbol] | [symbol] | [symbol] | [symbol] | [symbol] | [symbol] | [symbol] |
| 9 | [symbol] | [symbol] | [symbol] | [symbol] | [symbol] | [symbol] | [symbol] | [symbol] |
| 10 | [symbol] | [symbol] | [symbol] | [symbol] | [symbol] | [symbol] | [symbol] | [symbol] |
| 11 | [symbol] | [symbol] | [symbol] | [symbol] | [symbol] | [symbol] | [symbol] | [symbol] |
| 12 | [symbol] | [symbol] | [symbol] | [symbol] | [symbol] | [symbol] | [symbol] | [symbol] |
| 13 | [symbol] | [symbol] | [symbol] | [symbol] | [symbol] | [symbol] | [symbol] | [symbol] |
| 14 | [symbol] | [symbol] | [symbol] | [symbol] | [symbol] | [symbol] | [symbol] | [symbol] |
| 15 | [symbol] | [symbol] | [symbol] | [symbol] | [symbol] | [symbol] | [symbol] | [symbol] |
| 16 | [symbol] | [symbol] | [symbol] | [symbol] | [symbol] | [symbol] | [symbol] | [symbol] |
| 17 | [symbol] | [symbol] | [symbol] | [symbol] | [symbol] | [symbol] | [symbol] | [symbol] |
| 18 | [symbol] | [symbol] | [symbol] | [symbol] | [symbol] | [symbol] | [symbol] | [symbol] |
| 19 | [symbol] | [symbol] | [symbol] | [symbol] | [symbol] | [symbol] | [symbol] | [symbol] |
| 20 | [symbol] | [symbol] | [symbol] | [symbol] | [symbol] | [symbol] | [symbol] | [symbol] |

| | | | |
|---|---|---|---|
| [symbol] | [symbol] | [symbol] | [symbol] |

Y/X range: [symbol]
Y/X average: [symbol] [symbol]
indicates data missing or illegible when filed

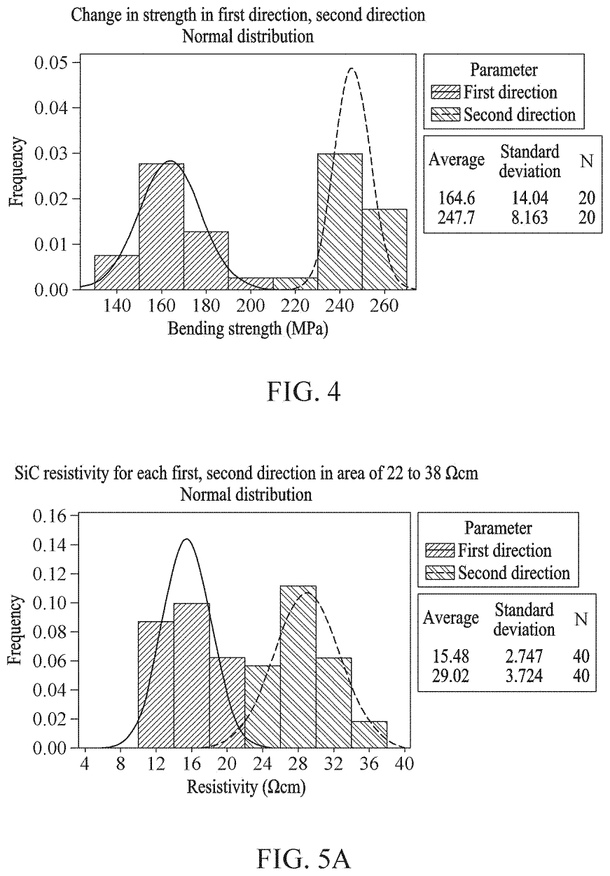

FIG. 4 is a graph showing distribution of strength values measured in the first direction and the second direction in the SiC structure according to the example embodiment of the present invention.

According to the example embodiment, an average strength in the first direction may be 133 Mpa to 200 Mpa, and an average strength in the second direction may be 225 Mpa to 260 Mpa.

According to the example embodiment, a value of the average strength in the first direction/the average strength in the second direction may be 0.55 to 0.9.

As an example of the SiC structure, it may be characterized that the average strength value in the second direction is higher than the average strength value in the first direction. Since the shape of the SiC structure used in the semiconductor process is mostly thin in the first direction, the strength measured in the second direction should be high, so that the operation is facilitated in carrying and mounting processes of a customer process.

As an example of the SiC structure proposed in the present invention, the SiC structure is manufactured and specimens with sizes of 20 mm (width)×4 mm (length)×4 mm (thickness) were prepared as 40 EA, 60 EA, 30 EA, and 20 EA by preparing, in the second direction, a structure of about 30 Ωcm, a structure of about 10 Ωcm, a structure of about 1 Ωcm, and a structure of less than 1 Ωcm, respectively, and resistivity values in the first direction and the second direction were measured and analyzed, respectively. The specific resistance was measured using EC-80P, Ts7D, and 4-Prob of Nexon KOTRA as a resistance measuring apparatus. The 4-Prob was in contact with each of the first surface and the second surface in the measurement to measure the resistivity. The 4-Prob used an NSCP type having a minimum probe length.

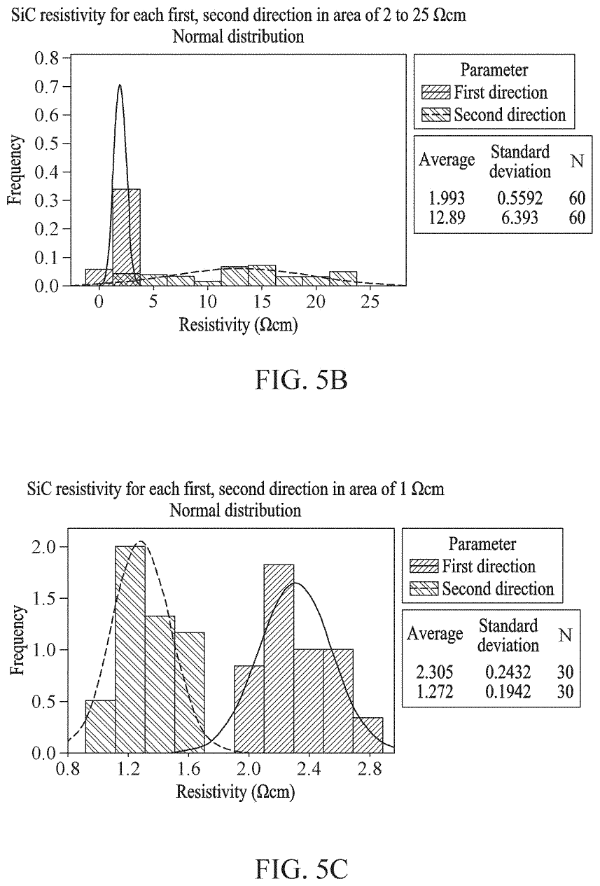

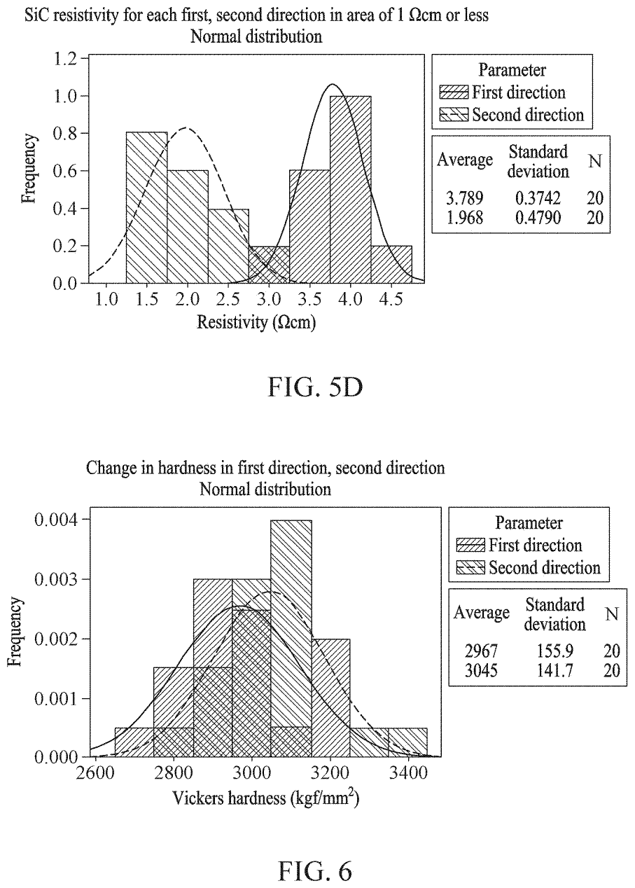

FIGS. 5A to 5D are graphs showing distribution of resistivity values (a structure having a second direction of about 30 Ωcm, a structure having a second direction of about 10 Ωcm, a structure having a second direction of about 1 Ωcm, and a structure having a second direction of 1 Ωcm or less) measured in the first direction and the second direction in the SiC structure according to the example embodiment of the present invention.

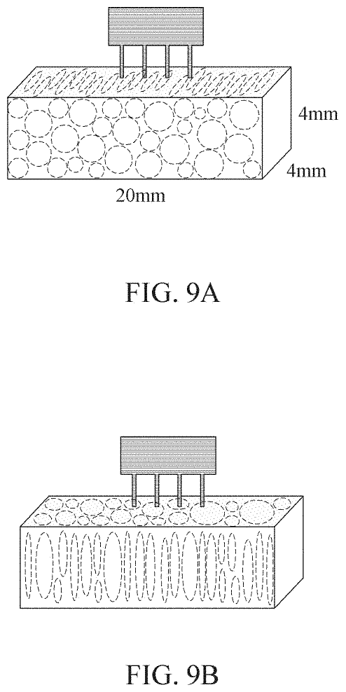

FIGS. 9A and 9B are diagrams illustrating a schematic method of measuring resistivities in a first direction (FIG. 9A) and a second direction (FIG. 9B) in the SiC structure according to the example embodiment of the present invention.

According to the example embodiment, the resistivity in the first direction may be 3.0×10⁻³ Ωcm to 25 Ωcm and the resistivity in the second direction may be 1.4×10⁻³ Ωcm to 40 Ωcm.

According to the example embodiment, a value of the resistivity in the first direction/the resistivity in the second direction may be 0.05 to 3.3.

Table 3 below shows values of measuring the sizes and the ratio of the resistivities measured in the first direction and the second direction with respect to total 40 EA specimens using the SiC structure of the present invention as described above. Table 3 below shows size data of resistivities classified for the SiC structure according to the example embodiment of the present invention in which the resistivity in the second direction is formed to about 30 Ωcm. The resistivity value may vary variously by controlling a dopant according to the use of the SiC structure.

TABLE 3
Size of resistivity

| | |
|---|---|
| First direction | Second direction |

| | | | | |
|---|---|---|---|---|
| 1 | 19.47 | 14.63 | 25.70 | 29.58 |
| 2 | 14.54 | 14.76 | 36.01 | 33.03 |
| 3 | 11.94 | 13.06 | 33.84 | 22.40 |
| 4 | 12.72 | 13.43 | 32.70 | 25.64 |
| 5 | 15.93 | 20.71 | 33.94 | 29.62 |
| 6 | 18.11 | 15.78 | 30.14 | 29.55 |
| 7 | 18.90 | 20.15 | 33.83 | 24.90 |
| 8 | 17.03 | 19.37 | 36.42 | 29.61 |
| 9 | 13.50 | 18.43 | 28.05 | 32.22 |
| 10 | 13.71 | 15.27 | 27.63 | 26.65 |
| 11 | 12.39 | 14.37 | 26.29 | 37.50 |
| 12 | 17.18 | 14.76 | 26.58 | 28.73 |
| 13 | 14.14 | 17.49 | 29.96 | 32.40 |
| 14 | 13.68 | 19.15 | 26.30 | 24.25 |
| 15 | 20.36 | 19.48 | 27.19 | 32.18 |
| 16 | 16.03 | 11.10 | 27.45 | 31.33 |
| 17 | 13.22 | 15.50 | 25.08 | 28.24 |
| 18 | 15.41 | 11.73 | 25.50 | 26.45 |
| 19 | 14.08 | 13.59 | 24.28 | 28.50 |
| 20 | 11.32 | 12.90 | 24.83 | 26.17 |

Table 3 above shows values of measuring the sizes and the ratio of the resistivities measured in the first direction and the second direction with respect to total 40 EA specimens using the SiC structure of the present invention as described above. Table 3 below shows size data of resistivities classified for the SiC structure according to the example embodiment of the present invention in which the resistivity in the second direction is formed to about 30 Ωcm. The resistivity value in the second direction may vary variously by controlling a dopant according to the use of the SiC structure.

In the example embodiment of the present invention according to the experimental results of Table 3 above, the resistivity in the first direction may be 10 Ωcm to 20 Ωcm, and the resistivity in the second direction may be 21 Ωcm to 40 Ωcm.

In the example embodiment of the present invention according to the experimental results of Table 3 above, the value of the resistivity of the first direction/the resistivity of the second direction may be 0.25 to 0.95.

Table 4 below shows values of measuring the sizes and the ratio of resistivities measured in the first direction and the second direction with respect to total 60 EA specimens using yet another SiC structure of the present invention in the same manner as described above. Table 4 below shows size data of resistivities classified for the SiC structure according to the example embodiment of the present invention in which the resistivity in the second direction is formed to about 10 Ωcm.

TABLE 4
Analysis of resistivity

| | |
|---|---|
| First direction | Second direction |

| | | | | |
|---|---|---|---|---|
| 1 | [symbol] | [symbol] | [symbol] | [symbol] |
| 2 | [symbol] | [symbol] | [symbol] | [symbol] |
| 3 | [symbol] | [symbol] | [symbol] | [symbol] |
| 4 | [symbol] | [symbol] | [symbol] | [symbol] |
| 5 | [symbol] | [symbol] | [symbol] | [symbol] |
| 6 | [symbol] | [symbol] | [symbol] | [symbol] |
| 7 | [symbol] | [symbol] | [symbol] | [symbol] |
| 8 | [symbol] | [symbol] | [symbol] | [symbol] |
| 9 | [symbol] | [symbol] | [symbol] | [symbol] |
| 10 | [symbol] | [symbol] | [symbol] | [symbol] |
| 11 | [symbol] | [symbol] | [symbol] | [symbol] |
| 12 | [symbol] | [symbol] | [symbol] | [symbol] |
| 13 | [symbol] | [symbol] | [symbol] | [symbol] |
| 14 | [symbol] | [symbol] | [symbol] | [symbol] |
| 15 | [symbol] | [symbol] | [symbol] | [symbol] |
| 16 | [symbol] | [symbol] | [symbol] | [symbol] |
| 17 | [symbol] | [symbol] | [symbol] | [symbol] |
| 18 | [symbol] | [symbol] | [symbol] | [symbol] |
| 19 | [symbol] | [symbol] | [symbol] | [symbol] |
| 20 | [symbol] | [symbol] | [symbol] | [symbol] |
| 21 | [symbol] | [symbol] | [symbol] | [symbol] |
| 22 | [symbol] | [symbol] | [symbol] | [symbol] |
| 23 | [symbol] | [symbol] | [symbol] | [symbol] |
| 24 | [symbol] | [symbol] | [symbol] | [symbol] |
| 25 | [symbol] | [symbol] | [symbol] | [symbol] |
| 26 | [symbol] | [symbol] | [symbol] | [symbol] |
| 27 | [symbol] | [symbol] | [symbol] | [symbol] |
| 28 | [symbol] | [symbol] | [symbol] | [symbol] |
| 29 | [symbol] | [symbol] | [symbol] | [symbol] |
| 30 | [symbol] | [symbol] | [symbol] | [symbol] |

[symbol]

indicates data missing or illegible when filed

According to the example embodiment according to the experimental result of Table 4 above, the resistivity in the first direction may be 0.8 Ωcm to 3.0 Ωcm, and the resistivity in the second direction may be 2.5 Ωcm to 25 Ωcm.

According to the example embodiment according to the experimental result of Table 4 above, the value of the resistivity of the first direction/the resistivity of the second direction may be 0.04 to 0.99.

Table 5 below shows values of measuring the sizes and the ratio of resistivities measured in the first direction and the second direction with respect to total 30 EA specimens using yet another SiC structure of the present invention in the same manner as described above. Table 5 below shows size data of resistivities classified for the SiC structure according to the example embodiment of the present invention in which the resistivity in the second direction is formed to about 1 Ωcm.

TABLE 5
Analysis of resistivity

| | First direction | Second direction |
|---|---|---|
| 1 | 2.64 | 1.13 |
| 2 | 2.27 | 1.40 |
| 3 | 2.21 | 1.30 |
| 4 | 2.50 | 1.10 |
| 5 | 2.10 | 1.20 |
| 6 | 2.20 | 1.40 |
| 7 | 1.95 | 1.10 |
| 8 | 2.30 | 1.60 |
| 9 | 2.00 | 1.56 |
| 10 | 1.97 | 1.50 |
| 11 | 2.30 | 1.50 |
| 12 | 2.40 | 1.50 |
| 13 | 2.30 | 1.10 |
| 14 | 2.20 | 1.20 |
| 15 | 2.30 | 0.99 |
| 16 | 2.00 | 1.30 |
| 17 | 2.60 | 1.30 |
| 18 | 2.90 | 1.00 |
| 19 | 2.20 | 1.18 |
| 20 | 2.70 | 1.52 |
| 21 | 2.50 | 1.13 |
| 22 | 2.49 | 1.60 |
| 23 | 2.21 | 1.40 |
| 24 | 2.28 | 1.10 |
| 25 | 1.90 | 0.92 |
| 26 | 2.10 | 1.20 |
| 27 | 2.40 | 1.10 |
| 28 | 2.00 | 1.20 |
| 29 | 2.10 | 1.20 |
| 30 | 1.92 | 0.99 |

According to the example embodiment according to the experimental result of Table 5 above, the resistivity in the first direction may be 1.8 Ωcm to 3.0 Ωcm, and the resistivity in the second direction may be 0.8 Ωcm to 1.7 Ωcm.

According to the example embodiment according to the experimental result of Table 5 above, the value of the resistivity of the first direction/the resistivity of the second direction may be 1.15 to 3.2.

Table 6 below shows values of measuring the sizes and the ratio of resistivities measured in the first direction and the second direction with respect to total 20 EA specimens using yet another SiC structure of the present invention in the same manner as described above. Table 6 below shows size data of resistivities classified for the SiC structure according to the example embodiment of the present invention in which the resistivity in the second direction is formed to less than 1 Ωcm.

TABLE 6
Analysis of resistivity

Unit: 10⁻³ Ωcm

| | First direction | Second direction |
|---|---|---|
| 1 | [symbol] | [symbol] |
| 2 | [symbol] | [symbol] |
| 3 | [symbol] | 2.06 |
| 4 | 4.01 | [symbol] |
| 5 | 4.06 | [symbol] |
| 6 | 3.64 | 2.11 |
| 7 | [symbol] | [symbol] |
| 8 | [symbol] | [symbol] |
| 9 | 4.21 | 1.40 |
| 10 | [symbol] | 2.27 |
| 11 | 4.4 [symbol] | 1.40 |
| 12 | [symbol] | [symbol] |
| 13 | [symbol] | [symbol] |
| 14 | [symbol] | [symbol] |
| 15 | [symbol] | [symbol] |
| 16 | [symbol] | [symbol] |
| 17 | 3.71 | 1.45 |
| 18 | 4.00 | 1.84 |
| 19 | [symbol] | [symbol] |
| 20 | 4.49 | [symbol] |

[symbol]

indicates data missing or illegible when filed

According to the example embodiment according to the experimental result of Table 6 above, the resistivity in the first direction may be 3.0×10⁻³ Ωcm to 5.0×10⁻³ Ωcm, and the resistivity in the second direction may be 1.4×10⁻³ Ωcm to 3.0×10⁻³ Ωcm.

According to the example embodiment according to the experimental result of Table 6 above, the value of the resistivity of the first direction/the resistivity of the second direction may be 1.1 to 3.3.

In the SiC structure, the resistivity of the SiC material may be adjusted by adding a dopant in raw gas according to a required usage, and accordingly, the resistivity in the second direction and the resistivity in the first direction can be adjusted according to an added amount of the dopant. As an example, in the SiC structure according to the example embodiment of the present invention, the concentration of the dopant to be added to control the resistivity may be 1×10¹⁸ atoms/cc or less.

The orientation of the crystal grains may play an important role in determining the resistivity in a specific direction. As an example, in the case of spherical crystal grains, since there are many interfaces even in any direction, electrons may be moved through defects and the like between the crystal grains. However, even in this case, when the number of electrons is saturated by adding a plurality of dopants, the plurality of electrons may pass through the interfaces between the crystal grains by a tunneling effect. Therefore, when the SiC structure at the concentration of the dopant of 1×10¹⁸ atoms/cc or less includes a crystal structure such as a needle shape elongated in a specific direction, the interfaces are not many, so that the electrons may move along the crystals.

When the resistivity of the SiC structure indicates a relatively high value or a lower value, a mechanism applied to each value is known to be different from each other. The SiC structure in a region zone where the resistivity is more than 1.7 Ωcm has an effect that the moving speed of free electrons in particles is fast to lower the resistivity in the first direction, but the SiC structure where the resistivity is 1.7 Ωcm or less has an effect that an intergranular moving speed of free electrons is fast to lower the resistivity in the second direction. Accordingly, in order to prevent the accumulation of charges on a partial surface of the SiC structure in the process, it is possible to determine a direction preferred as a moving path of electrons and design an appropriate resistivity value by considering the structure of the chamber and the equipment design.

According to an example, since the resistance in the first direction may be relatively small, the movement of charges in the first direction is facilitated. As a result, when the SiC structure of the present invention is placed in an environment with a lot of plasma entering in the first direction, it is possible to prevent the charges from being accumulated on the surface of the SiC structure. Therefore, it is possible to improve an arcing problem caused by the charge accumulation on the surface of the SiC structure.

If a large amount of plasma enters the SiC structure in the second direction with a relatively high resistivity value, high charge accumulation occurs on the surface of the SiC structure to cause an arching problem during the process. This problem may be the largest cause that causes the defects of the manufactured components.

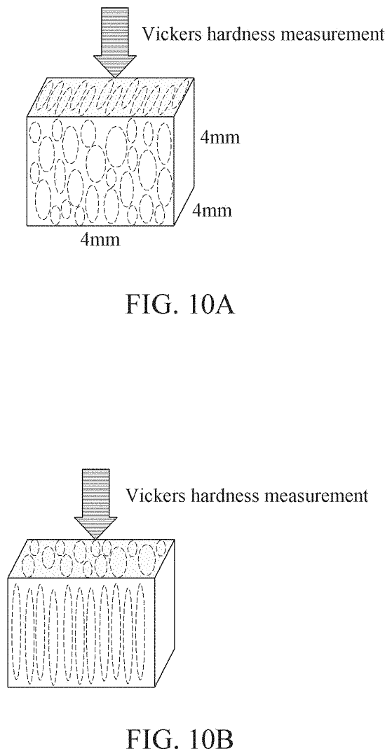

As an example of the SiC structure proposed in the present invention, two specimens with sizes of 4 mm (width)×4 mm (length)×4 mm (height) were prepared and the hardness was measured using a Vickers hardness machine based on KS B 0811 and measured by directly pressing a measured surface in the first direction/second direction as illustrated in FIGS. 10A and 10B. After the measurement, the hardness value was calculated by Equation below, and Vickers hardness values in the first direction and the second direction were measured at a total of 10 points, and the result thereof was analyzed.

$$HV = \frac{0.1891 F}{{d}^{2}} [ N / {mm}^{2} ]$$

HV: Vickers hardness, F: Load (N), d: Mean of diagonal lengths of pressing spots (mm)

FIG. 6 is a graph showing distribution of hardness values measured in the first direction and the second direction, as an example of the SiC structure according to the example embodiment of the present invention.

FIGS. 10A and 10B are diagrams illustrating a schematic method of measuring hardness in a first direction (FIG. 10A) and a second direction (FIG. 10B) in the SiC structure according to the example embodiment of the present invention.

As an example of the SiC structure proposed in the present invention, it can be confirmed that the hardness values in the first direction and the second direction represent almost equal values as compared with other physical property indexes.

Table 7 below shows values of measuring the sizes and the ratio of the hardness measured in the first direction and the second direction at total of 10 points with respect to two specimens as an example of the SiC structure of the present invention as described above.

TABLE 7
Analysis of hardness

| | First direction | | Second direction | |
|---|---|---|---|---|
| | Specimen 1 | Specimen 2 | Specimen 1 | Specimen 2 |
| 1 | 2 [symbol] 90 | 2736 | 3440 | 2972 |
| 2 | 3014 | 3240 | 3058 | 3102 |
| 3 | 2850 | 3014 | 2972 | 2972 |
| 4 | 2812 | 3240 | 2972 | 305 [symbol] |
| 5 | 2850 | 3014 | 2 [symbol] 12 | 2931 |
| 6 | 2931 | 2773 | 305 [symbol] | 3014 |
| 7 | 2972 | 3193 | 3147 | 2890 |
| 8 | 3014 | 2850 | 2 [symbol] 90 | 305 [symbol] |
| 9 | 2812 | 3193 | 3014 | 3288 |
| 10 | 2890 | 3058 | 3102 | 3147 |

[symbol]

indicates data missing or illegible when filed

According to the example embodiment, the hardness of the SiC structure may be 2800 kg_{f}/mm² to 3300 kg_{f}/mm² regardless of a direction.

According to the example embodiment, a value of the hardness in the first direction/the hardness in the second direction may be 0.85 to 1.15.

As an example of the SiC structure proposed in the present invention, 8 specimens with sizes of 4 mm (width)×4 mm (length)×2 mm (height) were prepared and XRD analysis in the first direction and the second direction was performed. As the analysis method, the hardness was measured using Regaku Dmax2000 equipment at a measuring angle of 10° to 80°, a scan step of 0.05, a scan speed of 10, and measuring power of 40 KV and 40 mA, and the secured graph was analyzed.

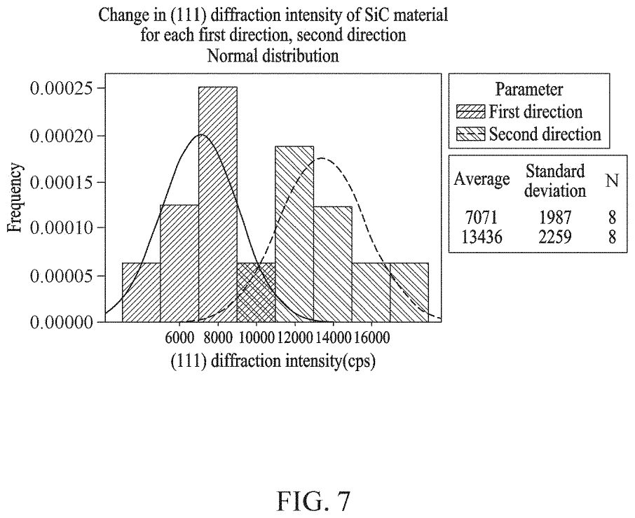

FIG. 7 is a graph showing distribution of diffraction intensity values of a (111) crystal plane of XRD analysis values measured in the first direction and the second direction in the SiC structure according to the example embodiment of the present invention.

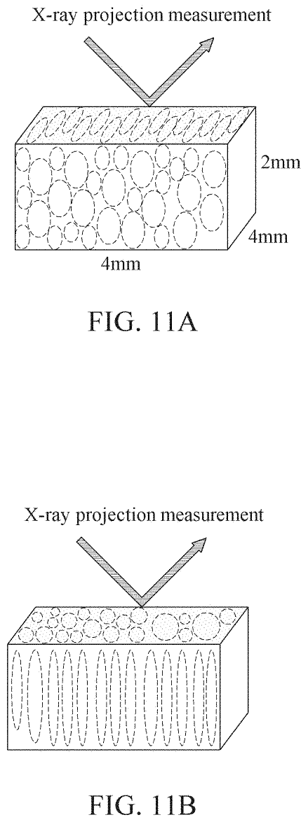

FIGS. 11A and 11B are diagrams illustrating a schematic method of performing XRD diffraction analysis in a first direction (FIG. 11A) and a second direction (FIG. 11B) in the SiC structure according to the example embodiment of the present invention.

Further, Table 8 below shows result values of performing XRD analysis in the first direction and the second direction with respect to 8 specimens, as an example of the SiC structure of the present invention as described above

TABLE 8
XRD Analysis

| | | Peak Intensity | | | | Peak Ratio | | ((200) + (220) + (311))/(111) Standard | | | | (111) Intensity Standard | | | |
|---|---|---|---|---|---|---|---|---|---|---|---|---|---|---|---|
| | | (111) | (200) | (220) | (311) | [symbol] | [symbol] | Min | Max | Average | Y/X | Min | Max | Average | Y/X |
| First | 1-1-Y | [symbol] | [symbol] | [symbol] | [symbol] | [symbol] | [symbol] | [symbol] | [symbol] | [symbol] | Y/X | [symbol] | [symbol] | [symbol] | Y/X |
| direction | 1-2-Y | [symbol] | [symbol] | [symbol] | [symbol] | [symbol] | [symbol] | | | | range | | | | range |
| | 2-1-Y | [symbol] | [symbol] | [symbol] | [symbol] | [symbol] | [symbol] | | | | [symbol] | | | | [symbol] |
| | 2-2-Y | [symbol] | [symbol] | [symbol] | [symbol] | [symbol] | [symbol] | | | | Y/X | | | | Y/X |
| | 3-1-Y | [symbol] | [symbol] | [symbol] | [symbol] | [symbol] | [symbol] | | | | average | | | | average |
| | 3-2-Y | [symbol] | [symbol] | [symbol] | [symbol] | [symbol] | [symbol] | | | | [symbol] | | | | [symbol] |
| | 4-1-Y | [symbol] | [symbol] | [symbol] | [symbol] | [symbol] | [symbol] | | | | | | | | |
| | 4-2-Y | [symbol] | [symbol] | [symbol] | [symbol] | [symbol] | [symbol] | | | | | | | | |
| Second | 1-1-X | [symbol] | [symbol] | [symbol] | [symbol] | [symbol] | [symbol] | [symbol] | [symbol] | [symbol] | | [symbol] | [symbol] | [symbol] | |
| direction | 1-2-X | [symbol] | [symbol] | [symbol] | [symbol] | [symbol] | [symbol] | | | | | | | | |
| | 2-1-X | [symbol] | [symbol] | [symbol] | [symbol] | [symbol] | [symbol] | | | | | | | | |
| | 2-2-X | [symbol] | [symbol] | [symbol] | [symbol] | [symbol] | [symbol] | | | | | | | | |
| | 3-1-X | [symbol] | [symbol] | [symbol] | [symbol] | [symbol] | [symbol] | | | | | | | | |
| | 3-2-X | [symbol] | [symbol] | [symbol] | [symbol] | [symbol] | [symbol] | | | | | | | | |
| | 4-1-X | [symbol] | [symbol] | [symbol] | [symbol] | [symbol] | [symbol] | | | | | | | | |
| | 4-2-X | [symbol] | [symbol] | [symbol] | [symbol] | [symbol] | [symbol] | | | | | | | | |

[symbol]

indicates data missing or illegible when filed

According to the example embodiment, with respect to peak intensities in a crystal plane direction for the first direction and the second direction of XRD analysis, [(200+220+311)]/(111) values may be 0.7 to 2.1 in the first direction and 0.4 to 0.75 in the second direction, respectively.

According to the example embodiment, with respect to peak intensities in a crystal plane direction for the first direction and the second direction of XRD analysis, the value in the first direction/the value in the second direction of the [(200+220+311)]/(111) values may be 1.0 to 4.4.

According to the example embodiment, with respect to peak intensities for the first direction and the second direction of XRD analysis, peak intensities of the (111) crystal plane direction may be 3200 to 10000 in the first direction and 10500 to 17500 in the second direction.

According to the example embodiment, with respect to peak intensities for the first direction and the second direction of XRD analysis, a value of the peak intensity of the (111) crystal plane direction in the first direction/the peak intensity of the (111) crystal plane direction in the second direction may be 0.2 to 0.95.

On the SiC crystal, the crystals formed on the (111) plane are more than those of other (200), (220), and (311) planes with different coordinate numbers per unit area to better withstand the impact of physical plasma particles there than to manufacture an SiC structure with an excellent anti-plasma property. Therefore, when the SiC structure has a low value in the peak ratio and has a high (111) diffraction intensity, a product having a relatively excellent anti-plasma property is manufactured to increase a usage time to be used in the plasma etching equipment.

In the case of the SiC structure manufactured according to an example, the peak intensity of the (111) crystal plane direction in the second direction may be implemented much higher than the peak intensity of the (111) crystal plane direction in the first direction. At this time, when the SiC component is fabricated, it is possible to expect the effect of improving the lifetime of the product when a direction (main etching direction) in which the plasma is irradiated is designed to be close to the second direction.

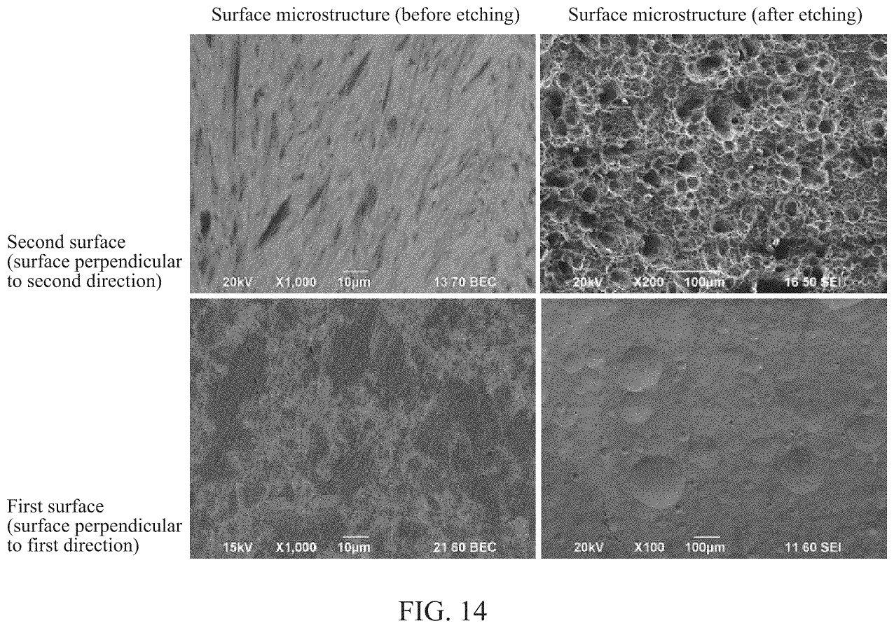

FIG. 14 is a photograph showing a microstructure (crystal grain structure) of a cross section in a first direction and a cross section in a second direction in the SiC structure according to the example embodiment of the present invention and an SEM photograph showing an etched form when the corresponding microstructure is exposed to plasma.

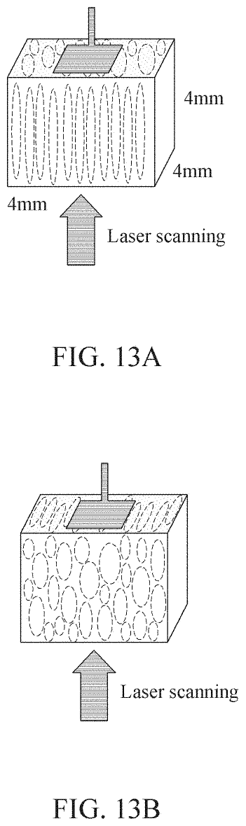

A cross section in the first direction and a cross section in the second direction of FIG. 14 were exposed to the plasma under the same condition. As an example, when the SiC structure is an edge ring, a first surface which is a surface perpendicular to the first direction may be an upper surface of the edge ring, and a second surface which is a surface perpendicular to the second direction may be a side surface of the edge ring. The cross section in the first direction may be an upper surface of the edge ring and the cross section in the second direction may be a side surface of the edge ring. Through an SEM photograph of a surface microstructure at the right of FIG. 13, it can be confirmed that the etching degree is greatly varied according to a direction to be exposed to the plasma.

Considering the effect, the second direction with the high (111) diffraction intensity may have a superior anti-plasma property. That is, when the second direction was designed as a surface on which the plasma is received, a product having an excellent anti-plasma property may be implemented.

As an example of the SiC structure proposed in the present invention, the temperature raised from room temperature to 1000° C. and a thermal expansion rate was measured to secure a thermal expansion coefficient. The thermal expansion rate was measured using TMA equipment (TMA402F1 Hyperion type of NETZSC). Three specimens with sizes of 4 mm (width)×4 mm (length)×4 mm (height) were measured according to the first direction and second direction. After the temperature was measured from room temperature to 1000° C., only measured values in a unit of 100° C. at 500° C. to 1000° C. were calculated and analyzed (due to an error in a low temperature period, measured except for the low temperature period).

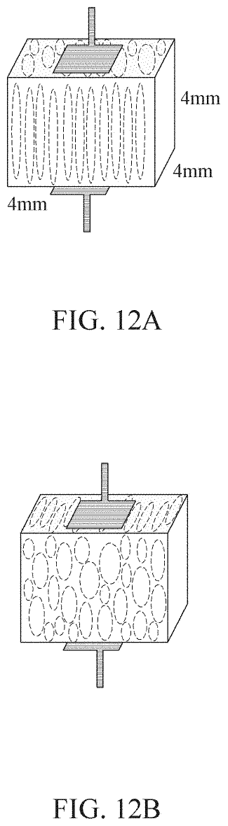

FIGS. 12A and 12B are diagrams illustrating a schematic method of performing thermal expansion rate analysis (to be described below) in a first direction (FIG. 12A) and a second direction (FIG. 12B) in the SiC structure according to the example embodiment of the present invention.

In the SiC structure used in the plasma chamber, the thermal expansion coefficient in a specific direction may be a very important factor in determining a precise etching amount. In the plasma chamber, the temperature is increased to a very high temperature during the process. At this time, when the thermal expansion coefficient in the first direction is relatively larger than the thermal expansion coefficient in the second direction, the height of a plasma etching object (wafer, etc.) in the chamber which is precisely set by considering an initial height of the corresponding component may be changed. As a result, a distance from the plasma source is changed to prevent an etching direction of the etching object from being precisely controlled and eventually, there is a problem that defects may occur. Therefore, in the case of some example embodiments, according to the design of the chamber and components to be applied, it is preferred that the thermal expansion coefficient in the first direction is lower, and it is possible to expect an effect of reducing the production of defects and increasing the component lifetime.

Table 9 below shows result values of performing the thermal expansion rate analysis in the first direction and the second direction with respect to two specimens fabricated with sizes of 4 mm (width)×4 mm (length)×4 mm (thickness), as an example of the SiC structure of the present invention.

TABLE 9
Analysis of thermal expansion rate

| | First direction | Second direction |
|---|---|---|
| 500-1000° C. | 4.3024E−06 | 4.9220E−06 |
| Measurement | 4.4805E−06 | 5.0645E−06 |
| DATA | 4.6199E−06 | 5.2697E−06 |
| | 4.6901E−06 | 5.2023E−06 |
| | 4.6381E−06 | 5.1349E−06 |
| | 4.5241E−06 | 5.2595E−06 |
| | 4.3024E−06 | 4.7197E−06 |
| | 4.4805E−06 | 4.9240E−06 |
| | 4.6199E−06 | 5.1828E−06 |
| | 4.6901E−06 | 5.2139E−06 |
| | 4.6381E−06 | 5.2766E−06 |
| | 4.5241E−06 | 5.3200E−06 |
| | 4.3024E−06 | 4.6581E−06 |
| | 4.4805E−06 | 4.9309E−06 |
| | 4.6199E−06 | 4.9763E−06 |
| | 4.6901E−06 | 5.0097E−06 |
| | 4.6381E−06 | 5.0450E−06 |
| | 4.5241E−06 | 5.0756E−06 |

According to the example embodiment, the thermal expansion coefficient in the first direction may be 4.0×10⁻⁶/° C. to 4.6×10⁻⁶/° C. and the thermal expansion coefficient in the second direction may be 4.7×10⁻⁶/° C. to 5.4×10⁻⁶/° C.

According to the example embodiment, a value of the thermal expansion coefficient in the first direction/the thermal expansion coefficient in the second direction may be less than 1.0.

As described above, the thermal expansion coefficient value in the first direction is designed to be relatively smaller than the thermal expansion coefficient value in the second direction to be manufactured as a component available for precise etching.

According to the example embodiment, a value of the thermal expansion coefficient in the first direction/the thermal expansion coefficient in the second direction may be 0.7 or more and less than 1.0.

FIGS. 13A and 13B are diagrams illustrating a schematic method of performing thermal conductivity analysis in a first direction (FIG. 13A) and a second direction (FIG. 13B) in the SiC structure according to the example embodiment of the present invention.

As an example of the SiC structure proposed in the present invention, two specimens with sizes of 4 mm (width)×4 mm (length)×1 mm (thickness) were prepared and thermal conductivities in the first direction and the second direction were measured. The thermal conductivity analysis was performed according to a laser type measurement method using LFA 447 NanoFlash equipment of NETZSCH. In order to measure the thermal conductivity according to a direction, when measuring the first direction, a measuring machine was in contact with the first surface (the surface perpendicular to the first direction) and a laser was irradiated to an opposite side to measure the thermal conductivity in the first direction. In the measurement in the second direction, thermal diffusivity was measured in the same manner. Such thermal diffusivity (mm²/s), the specific heat (Cp), and the density were calculated by the following Equation based on 0.67 J/g/K and 3.21 g/cm³, respectively, and the thermal conductivity was measured.

Thermal conductivity [W/mK]=thermal diffusivity (mm²/s)×specific heat (J/g/K)×density (g/cm³)

Table 10 below shows result values of performing thermal conductivity analysis in the first direction and the second direction with respect to 8 EA specimens, as an example of the SiC structure of the present invention as described above.

TABLE 10
Analysis of thermal conductivity

| | Temper- | Diffu- | | | Conduc- | |
|---|---|---|---|---|---|---|
| | ature | sivity | [symbol] | density | tivity | |
| | [° C.] | (mm2/s) | (J/g/K) | (g/cm3) | [W/mK] | average |
| First | [symbol] | [symbol] | [symbol] | [symbol] | [symbol] | [symbol] |
| direction | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| Second | [symbol] | [symbol] | [symbol] | [symbol] | [symbol] | [symbol] |
| direction | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |
| | [symbol] | [symbol] | [symbol] | [symbol] | [symbol] | |

[symbol]

indicates data missing or illegible when filed

According to the example embodiment, the thermal conductivity in the first direction may be 215 W/mk to 260 W/mk, and the thermal conductivity in the second direction may be 280 W/mk to 350 W/mk.

According to the example embodiment, a value of the thermal conductivity in the first direction/the thermal conductivity in the second direction may be less than 1.0.

According to the example embodiment, a value of the thermal conductivity in the first direction/the thermal conductivity in the second direction may be 0.65 to less than 1.0.

In the plasma chamber, the temperature is increased to a very high temperature during the process. In the SiC structure used in the plasma chamber, the thermal conductivity value in a specific direction may also be related to the displacement of cooling gas in the equipment. At this time, the SiC structure may be used to be placed or mounted in a direction perpendicular to a support part (a lower supporter including an electrostatic chuck or an upper supporter supporting a susceptor or upper electrode plate), and at this time, some support parts may include a cooling means (equipment of a cooling gas passage and the like) according to a structure of the chamber.

In this case, when considering the structure of the cooling means in the chamber, as the thermal conductivity in the first direction is lowered, the heat transfer to a height direction of the SiC structure is not easily performed to secure the temperature uniformity of the wafer, thereby increasing the productivity of the product.

According to the example embodiment, the SiC structure may include a first surface which is most exposed to the plasma and developed in a direction perpendicular to the first direction and a second surface which is perpendicular to the first surface and developed in a direction perpendicular to the second direction, and in the SiC structure, at least a part of the first surface (a lower surface of the structure according to an example) may be in contact with the support part.

According to the example embodiment, the SiC structure may be one of an edge ring, a susceptor, and a shower head.

The SiC structure according to the present invention may be manufactured by a method applied in the technical field of the present invention, and for example, may be formed by using the CVD, and may be formed by applying Si source gas, C source gas, general carrying gas such as hydrogen, nitrogen, helium, and argon, and the like. For example, the CVD may be performed under a process condition applied to the technical field of the present invention, and for example, the SiC material may be prepared using a deposition apparatus used in the technical field of the present invention.

As an example, the SiC structure of the present invention may be designed so that Si source gas and C source gas are injected to a target through an inlet to be injected individually and/or simultaneously in the CVD deposition chamber, and at this time, so that the Si source gas and the C source gas are injected from one or more inlets.

As an example, the SiC structure may be manufactured by including additional dopants in addition to Si and C. Even in this case, the SiC structure may be manufactured by a method applied in the technical field of the present invention, and for example, may be formed by using the CVD, and may be formed by applying Si source gas, C source gas, general carrying gas such as hydrogen, nitrogen, helium, and argon, and the like. For example, a priority growth crystal direction of an SiC coating film is changed by adjusting the growth rate during the deposition of SiC to change a diffraction intensity ratio (I). A main growth crystal direction and a crystal grain size may be adjusted by adjusting the growth speed. The growth speed can be adjusted through a control of the injection speed and by adjusting the temperature in a furnace. On the other hand, if the growth rate is lowered, a denser SiC layer is generated, so that an effect of increasing the strength and hardness may be expected.

According to the example embodiment of the present invention, the SiC structure formed by the CVD method may be a component of a semiconductor manufacturing apparatus requiring an anti-plasma property, such as an edge ring, a susceptor, and a shower head including SiC.

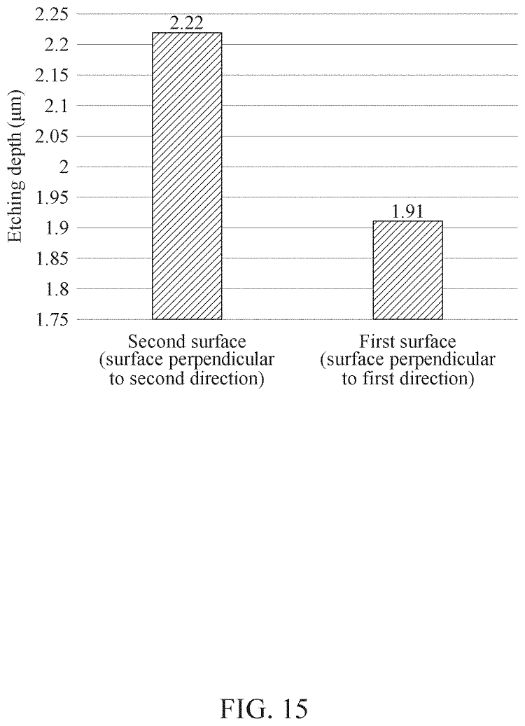

FIG. 15 is a graph of analyzing a plasma etching amount in a first direction and a plasma etching amount in a second direction in the SiC structure according to the example embodiment of the present invention.

Through FIG. 15, in the case of using the SiC structure proposed in the present invention, it was confirmed that in the etching to the plasma in the first surface and the second surface, the first surface was improved about 14% as compared with the second surface. This is because in the (111) priority growth in the terms of crystallinity, the first surface is superior to the second surface, and accordingly, when manufacturing the SiC structure such as an edge ring, it may be advantageous in the lifetime of the product usage that the surface mainly receiving the plasma is fabricated as the first surface.

According to the example embodiment, the SiC structure includes a first surface developed in a direction perpendicular to the first direction and a second surface developed in a direction perpendicular to the second direction, and the total sum of the areas of the first surface may be larger than the total sum of the areas of the second surface.

An example of the SiC structure may be an edge ring in which the total sum of the area of the first surface is at least two times larger than the total sum of the areas of the second surface.

As described above, although the example embodiments have been described by the limited example embodiments and the drawings, various modifications and variations are possible from the above description by those skilled in the art. For example, even if the described techniques are performed in a different order from the described method, and/or components described above are coupled or combined in a different form from the described method, or replaced or substituted by other components or equivalents, an appropriate result can be achieved.

Therefore, other implementations, other example embodiments, and equivalents to the appended claims fall within the scope of the claims to be described below.

1. (canceled)

2. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and the crystal grains are aligned so as to have a maximum length in −45° to +45° directions based on the first direction.

3. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and a value (aspect ratio) of the length in the first direction of the crystal grains/the length in the second direction of the crystal grains is 1.2 to 20.

4. The SiC structure, formed by the CVD method of claim 2, wherein the SiC structure includes a first surface which is most exposed to the plasma and developed in a direction perpendicular to the first direction and a second surface which is perpendicular to the first surface and developed in a direction perpendicular to the second direction.

5. The SiC structure, formed by the CVD method of claim 2, wherein an average strength in the first direction is 133 Mpa to 200 Mpa and an average strength in the second direction is 225 Mpa to 260 Mpa.

6. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and a value of the average strength in the first direction/the average strength in the second direction is 0.55 to 0.9.

7. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and a resistivity in the first direction is 3.0×10⁻³ Ωcm to 25 Ωcm, and a resistivity in the second direction is 1.4×10⁻³ Ωcm to 40 Ωcm.

8. (canceled)

9. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and a resistivity in the first direction is 10 Ωcm to 20 Ωcm, and a resistivity in the second direction is 21 Ωcm to 40 Ωcm.

10. The SiC structure, formed by the CVD method of claim 2, wherein a value of a resistivity in the first direction/a resistivity in the second direction is 0.25 to 0.95.

11. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and a resistivity in the first direction is 0.8 Ωcm to 3.0 Ωcm, and a resistivity in the second direction is 2.5 Ωcm to 25 Ωcm.

12. The SiC structure, formed by the CVD method of claim 2, wherein a value of a resistivity in the first direction/a resistivity in the second direction is 0.04 to 0.99.

13. The SiC structure, formed by the CVD method of claim 2, wherein a resistivity in the first direction is 1.8 Ωcm to 3.0 Ωcm, and a resistivity in the second direction is 0.8 Ωcm to 1.7 Ωcm.

14. The SiC structure, formed by the CVD method of claim 2, wherein a value of a resistivity in the first direction/a resistivity in the second direction is 1.15 to 3.2.

15. The SiC structure, formed by the CVD method of claim 2, wherein a resistivity in the first direction is 3.0×10⁻³ Ωcm to 5.0×10⁻³ Ωcm, and a resistivity in the second direction is 1.4×10⁻³ Ωcm to 3.0×10⁻³ Ωcm.

16. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and a value of a resistivity in the first direction/a resistivity in the second direction is 1.1 to 3.3.

17. The SiC structure, formed by the CVD method of claim 2, wherein a hardness of the SiC structure is 2800 kg_{f}/mm² to 3300 kg_{f}/mm² regardless of a direction.

18. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and a value of a hardness in the first direction/a hardness in the second direction is 0.85 to 1.15.

19. The SiC structure, formed by the CVD method of claim 2, wherein with respect to peak intensities in a crystal plane direction for the first direction and the second direction of XRD analysis, [(200+220+311)]/(111) values are 0.7 to 2.1 in the first direction and 0.4 to 0.75 in the second direction, respectively.

20. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and with respect to peak intensities in a crystal plane direction for the first direction and the second direction of XRD analysis, a value of the first direction/a value of the second direction of a [(200+220+311)]/(111) value is 1.0 to 4.4.

21. The SiC structure, formed by the CVD method of claim 2, wherein with respect to peak intensities for the first direction and the second direction of XRD analysis, the peak intensities in a (111) crystal plane direction are 3200 to 10000 in the first direction and 10500 to 17500 in the second direction, respectively.

22. An SiC structure, formed by a CVD method, which is used such that the SiC structure is exposed to plasma inside a chamber, wherein the SiC structure includes a crystal grain structure in which a length in a first direction is longer than a length in a second direction when defining a direction perpendicular to a surface most exposed to the plasma as the first direction and a direction horizontal to the surface most exposed to the plasma as the second direction and with respect to peak intensities for the first direction and the second direction of XRD analysis, a value of a peak intensity in a (111) crystal plane direction of the first direction/a peak intensity in the (111) crystal plane direction of the second direction is 0.2 to 0.95.

23. The SiC structure, formed by the CVD method of claim 2, wherein a thermal expansion coefficient in the first direction is 4.0×10⁻⁶/° C. to 4.6×10⁻⁶/° C., and the thermal expansion coefficient in the second direction is 4.7×10⁻⁶/° C. to 5.4×10⁻⁶/° C.

24. (canceled)

25. The SiC structure, formed by the CVD method of claim 2, wherein a value of a thermal expansion coefficient in the first direction/a thermal expansion coefficient in the second direction is 0.7 or more and less than 1.0.

26. The SiC structure, formed by the CVD method of claim 2, wherein a thermal conductivity in the first direction is 215 W/mk to 260 W/mk, and a thermal conductivity in the second direction is 280 W/mk to 350 W/mk.

27. (canceled)

28. The SiC structure, formed by the CVD method of claim 2, wherein a value of a thermal conductivity in the first direction/a thermal conductivity in the second direction is 0.65 to less than 1.0.

29. The SiC structure, formed by the CVD method of claim 2, wherein the SiC structure includes a first surface which is most exposed to the plasma and developed in a direction perpendicular to the first direction and a second surface which is perpendicular to the first surface and developed in a direction perpendicular to the second direction, wherein in the SiC structure, at least a part of the first surface is in contact with a support part.

30. The SiC structure, formed by the CVD method of claim 2, wherein the SiC structure is one of an edge ring, a susceptor, and a shower head.

31. The SiC structure, formed by the CVD method of claim 2, wherein the SiC structure includes a first surface which is most exposed to the plasma and developed in a direction perpendicular to the first direction and a second surface which is perpendicular to the first surface and developed in a direction perpendicular to the second direction, wherein a total sum of areas of the first surface is larger than a total sum of areas of the second surface.
